(19) United States
(12) Patent Application Publication
(10) Pub. No.: US 2026/0334225 A1
(43) Pub. Date: Oct. 22, 2026

(54) INTEGRATED CIRCUIT PACKAGES AND METHODS OF FORMING THE SAME

(71) Applicant: Taiwan semiconductor Manufacturing Co., Ltd., Hsinchu (TW)

(72) Inventors: Wensen Hung, Zhubei City (TW); Wei-Kong Sheng, Chu-Nan (TW); Yen-Pu Chen, Hsinchu (TW); Tsung-Yu Chen, Hsinchu (TW)

(21) Appl. No.: 19/718,747

(22) Filed: Jun. 24, 2026

Related U.S. Application Data
(62) Division of application No. 18/656,085, filed on May 6, 2024.

(51) Int. Cl. H10W 40/28; H05K 1/183; H05K 3/306; H10P 74/20; H10W 90/00; H05K 1/02; H10W 72/00; H10W 74/10; H10W 74/15

(52) U.S. Cl. CPC H10W 40/28; H05K 1/183; H05K 3/308; H10P 74/207; H10W 90/00; H05K 1/0201; H10W 72/0198; H10W 74/10; H10W 74/15; H10W 90/722; H10W 90/724; H10W 90/734

(57) ABSTRACT

A method includes forming a package structure, where forming the package structure includes attaching a package component to a front side of a package substrate, where the package component includes a first die, and attaching a second die to a back side of the package substrate, and inserting a portion of the package structure into a first cavity of a fixture, where the fixture includes a thermoelectric cooling (TEC) module that is disposed in a second cavity of the fixture, where the second cavity of the fixture is disposed within a bottom surface of the first cavity, where after inserting the portion of the package structure into the first cavity of the fixture, the second die is in thermal contact with the TEC module, and where the fixture is coupled to a printed circuit board (PCB).

### CROSS-REFERENCE TO RELATED APPLICATIONS

This application is a divisional of U.S. Patent Application No. 18/656,085, filed on May 6, 2024, which application is hereby incorporated herein by reference.

### BACKGROUND

Since the development of the integrated circuit (IC), the semiconductor industry has experienced continued rapid growth due to continuous improvements in the integration density of various electronic components (i.e., transistors, diodes, resistors, capacitors, etc.). For the most part, these improvements in integration density have come from repeated reductions in minimum feature size, which allows more components to be integrated into a given area.

These integration improvements are essentially two-dimensional (2D) in nature, in that the area occupied by the integrated components is essentially on the surface of the semiconductor wafer. The increased density and corresponding decrease in area of the integrated circuit has generally surpassed the ability to bond an integrated circuit chip directly onto a substrate. Interposers have been used to redistribute ball contact areas from that of the chip to a larger area of the interposer. Further, interposers have allowed for a three-dimensional (3D) package that includes multiple chips. Other packages have also been developed to incorporate 3D aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 13 are cross-sectional views of intermediate stages in the manufacturing of a package structure, in accordance with some embodiments.

FIGS. 14A-14B are cross-sectional views of intermediate stages during the electrical testing of the package structure, or in the manufacturing of a combined package structure, in accordance with some embodiments.

FIG. 15 is a cross-sectional view of intermediate stages during the electrical testing of the package structure, or in the manufacturing of a combined package structure, in accordance with some other embodiments.

FIGS. 16A-16B are cross-sectional views of intermediate stages during the electrical testing of a package structure, or in the manufacturing of a combined package structure, in accordance with some other embodiments.

FIGS. 17A-17B are cross-sectional views of intermediate stages during the electrical testing of a package structure, or in the manufacturing of a combined package structure, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments include methods for forming a device package (e.g., a chip-on-wafer-on-substrate (CoWoS®) package comprising a package component (e.g., a chip-on-wafer package component comprising one or more first semiconductor chips bonded to an interposer) and a package substrate. A first side (also referred to as a front side) of the package substrate may be bonded to a side of the interposer opposing the one or more first semiconductor chips. A second semiconductor chip may be bonded to a second side (also referred to as a back side) of the package substrate, wherein the second side of the package substrate is on an opposite side of the package substrate as the first side of the package substrate. The electrical characteristics, functionality, and performance of the device package may be assessed and tested by establishing temporary electrical connections between the device package and specific test points on a printed circuit board (PCB). The temporary electrical connections may be made using a fixture comprising a top portion (also referred to as a top guide plate), a bottom portion (also referred to as a bottom guide plate), and socket pins that extend through the top portion and the bottom portion of the fixture. Each of the socket pins may comprise a bottom plunger that extends below the bottom surface of the fixture and that is inserted into a respective hole in the PCB that is aligned with an intended contact point (e.g., contact pad) in the PCB. Each socket pin may also comprise a top plunger. These contact points may correspond to test points, programming interfaces, or other areas where temporary electrical connections are required. After the bottom plunger of each socket pin is inserted into a respective hole in the PCB, the socket pin is in physical and electrical contact with the contact point. Each socket pin further comprises a housing disposed between the top plunger and the bottom plunger. A spring mechanism is disposed in the housing, and this spring mechanism allows the socket pin to compress or retract when pressure is applied and return to its extended position when the force is removed.

The top portion of the fixture comprises a first cavity that extends partially through the top portion of the fixture. A second cavity is disposed in the remainder of the top portion of the fixture. For example, the second cavity may be disposed within the bottom surface of the first cavity. A width of the first cavity is greater than a width of the second cavity. A thermoelectric cooling (TEC) module (also referred to as a peltier device or thermoelectric cooler), is disposed in the second cavity, wherein the TEC module is attached to a bottom surface of the second cavity using an adhesive layer (e.g., a die attach film). A top plunger of each socket pin may protrude above a bottom surface of the first cavity and above a top surface of the TEC module that is disposed within the second cavity. The device package is then positioned within the first cavity of the fixture, wherein the device package is secured between sidewalls of the first cavity ensuring proper alignment of the top plungers with respective land grid array (LGA) pads on the back side of the package substrate of the device package. The fixture is designed to securely hold and support the device package in place during testing and prevent lateral movement of the device package during testing. After the device package is positioned within the first cavity of the fixture, each top plunger of each socket pin is in physical and electrical contact with a respective LGA pad on the package substrate ensuring electrical connection between the device package and the PCB through the socket pins.

In addition, after the device package is positioned within the first cavity of the fixture to undergo testing, the TEC module is in physical contact with a bottom surface of the second semiconductor chip by way of a thermal interface material (TIM) disposed between the TEC module and the second semiconductor chip. Advantageous features of some embodiments disclosed herein includes enhanced cooling of the device package (e.g., including the second semiconductor chip) from the back side of the package substrate during testing and operation. This enhanced cooling may allow the bonding and utilization of a greater number of semiconductor chips in the device package on both the front side and the back side of the package substrate, since the enhanced cooling may adequately accommodate the additional heat generated by an increased number of semiconductor chips. In addition, the enhanced cooling of the device package (e.g., including the second semiconductor chip) from the back side of the package substrate efficiently eliminates heat traps and mitigates hot spots during testing and operation of the device package, which results in improved thermal management and overall temperature control of the device package. This further allows for power to be delivered to the device package from the back side of the package substrate without the formation of hot spots and heat traps within the device package.

Embodiments will be described with respect to a specific context, namely a Die-Interposer-Substrate stacked package using Chip-on-Wafer-on-Substrate (CoWoS) processing. Other embodiments may also be applied, however, to other packages, such as an Integrated Fan-Out (InFO) package, and other processing.

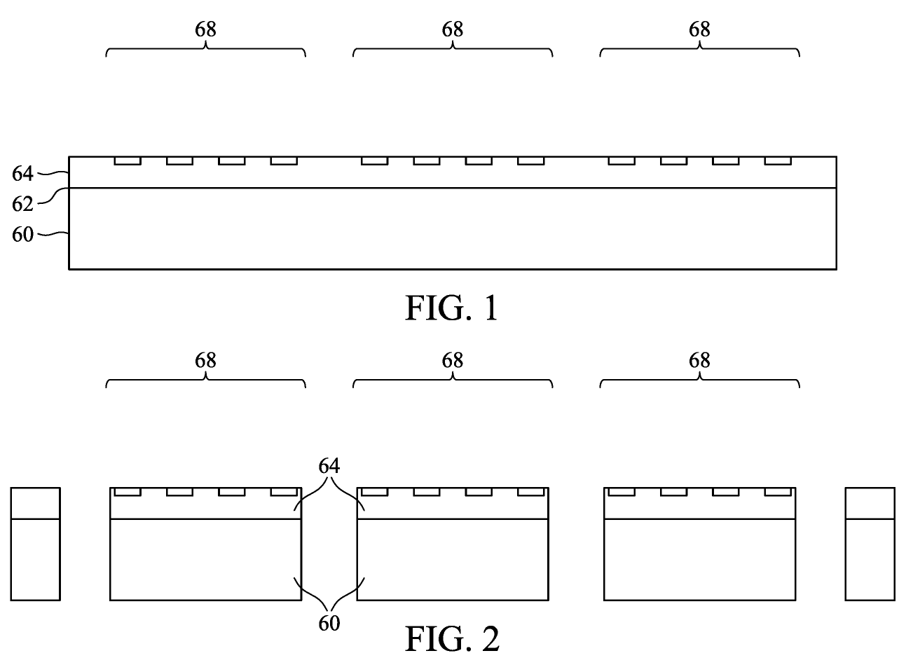

FIGS. 1 -13 illustrate cross-sectional views of intermediate stages in the manufacturing of a package structure 10 in accordance with some embodiments. FIG. 1 illustrates one or more dies 68. A main body 60 of the dies 68 may comprise any number of dies, substrates, transistors, active devices, passive devices, or the like. In an embodiment, the main body 60 may include a bulk semiconductor substrate, semiconductor-on-insulator (SOI) substrate, multi-layered semiconductor substrate, or the like. The semiconductor material of the main body 60 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The main body 60 may be doped or undoped. Devices, such as transistors, capacitors, resistors, diodes, and the like, may be formed in and/or on an active surface 62 of the main body 60.

An interconnect structure 64 comprising one or more dielectric layer(s) and respective metallization pattern(s) is formed on the active surface 62. The metallization pattern(s) in the dielectric layer(s) may route electrical signals between the devices, such as by using vias and/or traces, and may also contain various electrical devices, such as capacitors, resistors, inductors, or the like. The various devices and metallization patterns may be interconnected to perform one or more functions. The functions may include memory structures, processing structures, sensors, amplifiers, power distribution, input/output circuitry, or the like. Additionally, die connectors, such as conductive pillars (for example, comprising a metal such as copper), are formed in and/or on the interconnect structure 64 to provide an external electrical connection to the circuitry and devices.

As an example to form a layer of the interconnect structure 64, an inter-metallization dielectric (IMD) layer may be formed. The IMD layer may be formed, for example, of a low-K dielectric material, such as phosphosilicate glass (PSG), borophosphosilicate glass (BPSG), fluorosilicate glass (FSG), SiOₓC_{y}, Spin-On-Glass, Spin-On-Polymers, silicon carbon material, compounds thereof, composites thereof, combinations thereof, or the like, by any suitable method known in the art, such as spinning, chemical vapor deposition (CVD), plasma-enhanced CVD (PECVD), high-density plasma chemical vapor deposition (HDP-CVD), or the like. A metallization pattern may be formed in the IMD layer, for example, by using photolithography techniques to deposit and pattern a photoresist material on the IMD layer to expose portions of the IMD layer that are to become the metallization pattern. An etch process, such as an anisotropic dry etch process, may be used to create recesses and/or openings in the IMD layer corresponding to the exposed portions of the IMD layer. The recesses and/or openings may be lined with a diffusion barrier layer and filled with a conductive material. The diffusion barrier layer may comprise one or more layers of tantalum nitride, tantalum, titanium nitride, titanium, cobalt tungsten, the like, or a combination thereof, deposited by atomic layer deposition (ALD), or the like. The conductive material of the metallization patterns may comprise copper, aluminum, tungsten, silver, and combinations thereof, or the like, deposited by CVD, physical vapor deposition (PVD), or the like. Any excessive diffusion barrier layer and/or conductive material on the IMD layer may be removed, such as by using a chemical mechanical polish (CMP). Additional layers of the interconnect structure 64 may be formed by repeating these steps.

In FIG. 2, the main body 60 including the interconnect structure 64 is singulated into individual dies 68. Typically, each of the dies 68 contains the same circuitry, such as the same devices and metallization patterns, although some or all of the dies 68 may have different circuitry. The singulation may include sawing, dicing, or the like.

Each of the dies 68 may include one or more logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. Also, in some embodiments, the dies 68 may be different sizes (e.g., different heights and/or surface areas), and in other embodiments, the dies 68 may be the same size (e.g., same heights and/or surface areas).

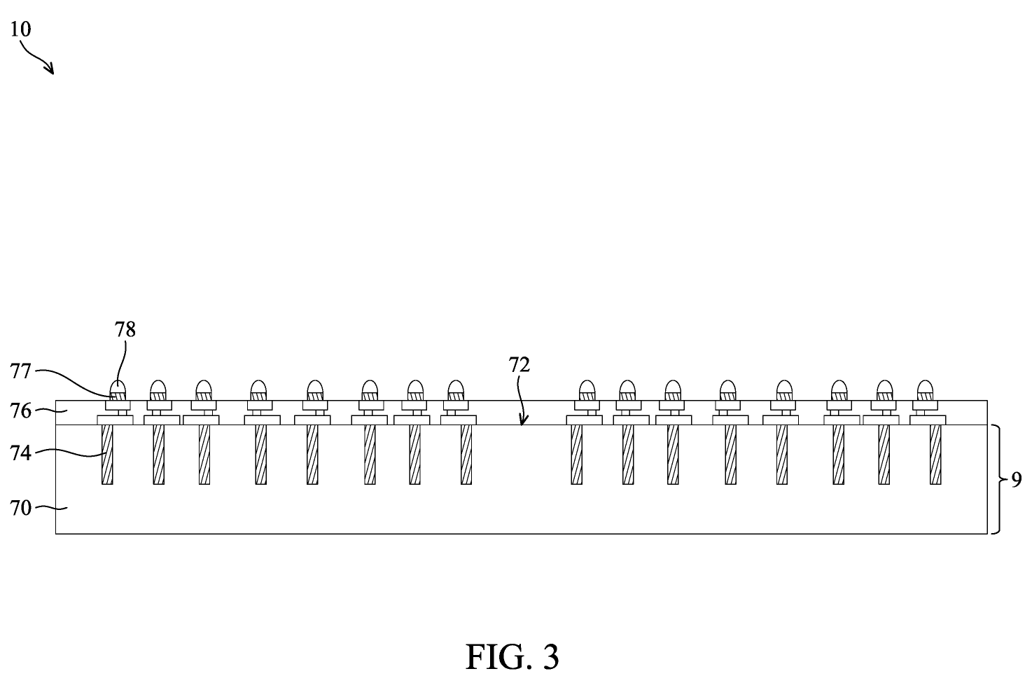

FIG. 3 illustrates one or more components 96 during processing. The components 96 may be interposers or other dies. A substrate 70 may form the main body of the components 96. The substrate 70 can be a wafer. The substrate 70 may comprise a bulk semiconductor substrate, SOI substrate, multi-layered semiconductor substrate, or the like. The semiconductor material of the substrate 70 may be silicon, germanium, a compound semiconductor including silicon germanium, silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 70 may be doped or undoped. Devices, such as transistors, capacitors, resistors, diodes, and the like, may be formed in and/or on a first surface 72, which may also be referred to as an active surface, of the substrate 70. In embodiments where the components 96 are interposers, the components 96 will generally not include active devices therein, although the interposer may include passive devices formed in and/or on a first surface 72. In such embodiments, the components 96 may be free of any active devices on the substrate 70.

Through-vias (TVs) 74 are formed to extend from the first surface 72 of substrate 70 into substrate 70. The TVs 74 are also sometimes referred to as through-substrate vias, or through-silicon vias when substrate 70 is a silicon substrate. The TVs 74 may be formed by forming recesses in the substrate 70 by, for example, etching, milling, laser techniques, a combination thereof, and/or the like. A thin dielectric material may be formed in the recesses, such as by using an oxidation technique. A thin barrier layer may be conformally deposited over the front side of the substrate 70 and in the openings, such as by CVD, ALD, PVD, thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material may be deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer is removed from the front side of the substrate 70 by, for example, CMP. Thus, the TVs 74 may comprise a conductive material and a thin barrier layer between the conductive material and the substrate 70.

Interconnect structure 76 is formed over the first surface 72 of the substrate 70, and is used to electrically connect the integrated circuit devices, if any, and/or TVs 74 together and/or to external devices. The interconnect structure 76 may include one or more dielectric layer(s) and respective metallization pattern(s) in the dielectric layer(s). The metallization patterns may comprise vias and/or traces to interconnect any devices and/or TVs 74 together and/or to an external device. The dielectric layers may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layers may be deposited by any suitable method known in the art, such as spinning, CVD, PECVD, HDP-CVD, or the like. A metallization pattern may be formed in the dielectric layer, for example, by using photolithography techniques to deposit and pattern a photoresist material on the dielectric layer to expose portions of the dielectric layer that are to become the metallization pattern. An etch process, such as an anisotropic dry etch process, may be used to create recesses and/or openings in the dielectric layer corresponding to the exposed portions of the dielectric layer. The recesses and/or openings may be lined with a diffusion barrier layer and filled with a conductive material. The diffusion barrier layer may comprise one or more layers of TaN, Ta, TiN, Ti, CoW, or the like, deposited by ALD, or the like, and the conductive material may comprise copper, aluminum, tungsten, silver, and combinations thereof, or the like, deposited by CVD, PVD, or the like. Any excessive diffusion barrier layer and/or conductive material on the dielectric layer may be removed, such as by using a CMP.

Electrical connectors 77/78 are formed at the top surface of the interconnect structure 76, such as on conductive pads that are formed in the dielectric layers of the interconnect structure 76. In some embodiments, the electrical connectors 77/78 include metal pillars 77 with metal cap layers 78, which may be solder caps, over the metal pillars 77. The electrical connectors 77/78 (including the pillars 77 and the cap layers 78) are sometimes referred to as micro bumps 77/78. In some embodiments, the metal pillars 77 include a conductive material such as copper, aluminum, gold, nickel, palladium, the like, or a combination thereof and may be formed by sputtering, printing, electro plating, electroless plating, CVD, or the like. The metal pillars 77 may be solder free and have substantially vertical sidewalls. In some embodiments, respective metal cap layers 78 are formed on the respective top surfaces of the metal pillars 77. The metal cap layers 78 may include nickel, tin, tin-lead, gold, copper, silver, palladium, indium, nickel-palladium-gold, nickel-gold, the like, or a combination thereof and may be formed by a plating process.

In another embodiment, the electrical connectors 77/78 do not include the metal pillars and are solder balls and/or bumps, such as controlled collapse chip connection (C4), electroless nickel immersion Gold (ENIG), electroless nickel electroless palladium immersion gold technique (ENEPIG) formed bumps, or the like. In such embodiments, the bump electrical connectors 77/78 may include a conductive material such as solder, copper, aluminum, gold, nickel, silver, palladium, tin, the like, or a combination thereof. The electrical connectors 77/78 may be formed by initially forming a layer of solder through methods such as evaporation, electroplating, printing, solder transfer, ball placement, or the like. Once a layer of solder has been formed on the structure, a reflow may be performed in order to shape the material into the desired bump shapes.

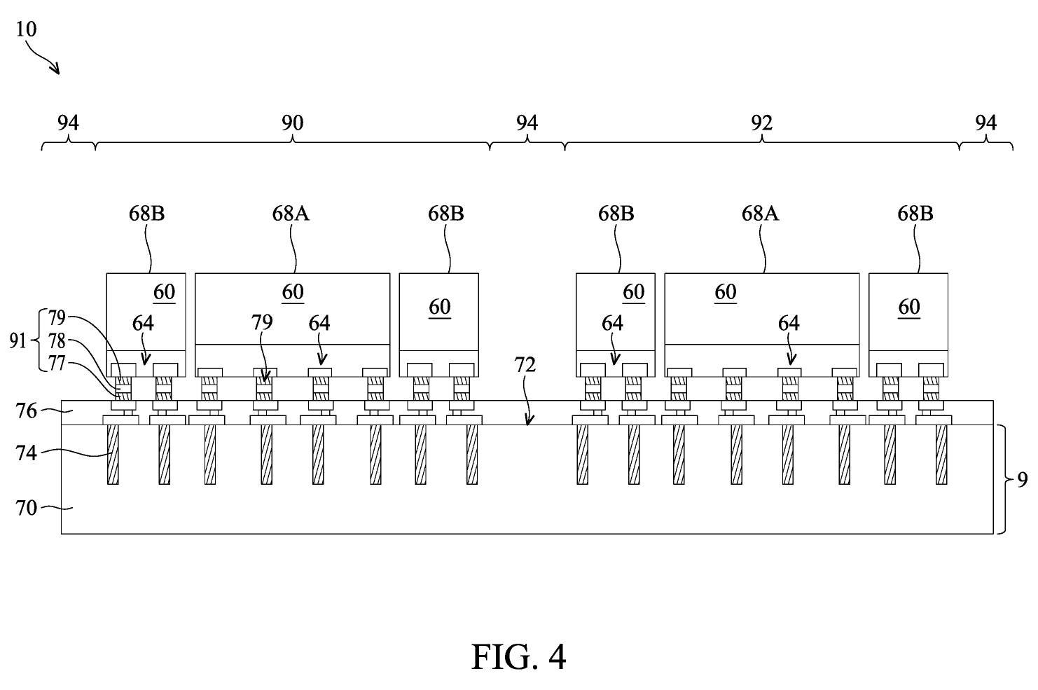

In FIG. 4, dies 68 (including dies 68A and dies 68B) are attached to the first side of the components 96, for example, through flip-chip bonding by way of the electrical connectors 77/78 and metal pillars 79 on the dies to form conductive joints 91. The metal pillars 79 may be similar to the metal pillars 77 and the description is not repeated herein. The dies 68 may be placed on the electrical connectors 77/78 using, for example, a pick-and-place tool. In some embodiments, the metal cap layers 78 are formed on the metal pillars 77 (as shown in FIG. 3), the metal pillars 79 of the dies 68, or both.

The dies 68A and the dies 68B may be different types of dies. In some embodiments, the dies 68A include logic dies (e.g., central processing unit, graphics processing unit, system-on-a-chip, field-programmable gate array (FPGA), microcontroller, or the like), memory dies (e.g., dynamic random access memory (DRAM) die, static random access memory (SRAM) die, or the like), power management dies (e.g., power management integrated circuit (PMIC) die), radio frequency (RF) dies, sensor dies, micro-electro-mechanical-system (MEMS) dies, signal processing dies (e.g., digital signal processing (DSP) die), front-end dies (e.g., analog front-end (AFE) dies), the like, or a combination thereof. In some embodiments, the dies 68A are system-on-a-chip (SoC) or a graphics processing unit (GPU) dies, and the dies 68B are memory dies that may utilized by the dies 68A. In some embodiments, the dies 68B include one or more memory dies, such as a stack of memory dies (e.g., DRAM dies, SRAM dies, High-Bandwidth Memory (HBM) dies, Hybrid Memory Cubes (HMC) dies, or the like). In the stack of memory dies embodiments, a die 68B can include both memory dies and a memory controller, such as, for example, a stack of four or eight memory dies with a memory controller. Also, in some embodiments, the dies 68B may be different sizes (e.g., different heights and/or surface areas) from the dies 68A, and in other embodiments, the dies 68B may be the same size (e.g., same heights and/or surface areas) as the dies 68A. In some embodiments, the dies 68B may be similar heights to those of the dies 68A (as shown in FIG. 4) or in some embodiments, the dies 68A and 68B may be of different heights.

The conductive joints 91 electrically couple the circuits in the dies 68, through the interconnect structures 64, to the interconnect structure 76 and the TVs 74 in the components 96. Additionally, the interconnect structure 76 electrically interconnects the dies 68A and the dies 68B to each other.

In some embodiments, before bonding the electrical connectors 77/78, the electrical connectors 77/78 are coated with a flux (not shown), such as a no-clean flux. The electrical connectors 77/78 may be dipped in the flux or the flux may be jetted onto the electrical connectors 77/78. In another embodiment, the flux may also be applied to the electrical connectors 79/78. In some embodiments, the electrical connectors 77/78 and/or 79/78 may have an epoxy flux (not shown) formed thereon before they are reflowed with at least some of the epoxy portion of the epoxy flux remaining after the dies 68 are attached to the components 96. This remaining epoxy portion may act as an underfill to reduce stress and protect the joints resulting from the reflowing the electrical connectors 77/78/79.

The bonding between the dies 68 and the components 96 may be a solder bonding or a direct metal-to-metal (such as a copper-to-copper or tin-to-tin) bonding. In an embodiment, the dies 68 are bonded to the components 96 by a reflow process. During this reflow process, the electrical connectors 77/78/79 are in contact to physically and electrically couple the dies 68 to the components 96. After the bonding process, an IMC (not shown) may form at the interface of the metal pillars 77/79 and the metal cap layers 78.

In FIG. 4 and subsequent figures, a first package region 90 and a second package region 92 for the formation of a first package and a second package, respectively, are illustrated. Scribe line regions 94 are between adjacent package regions. As illustrated in FIG. 4, a single die 68A and multiple dies 68B are attached in each of the first package region 90 and the second package region 92.

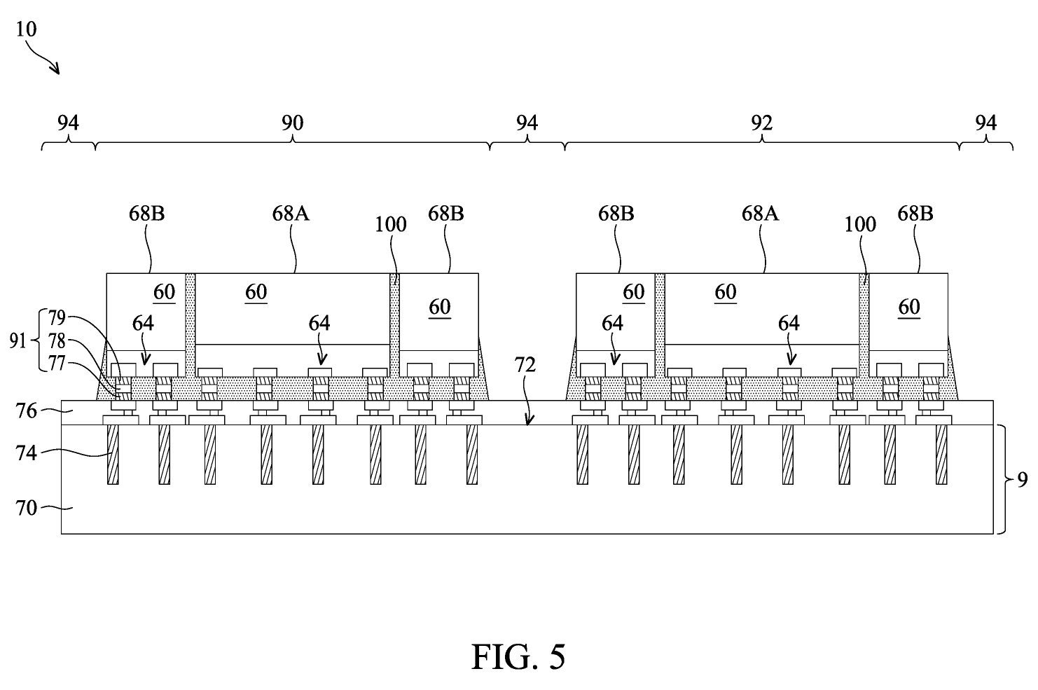

In FIG. 5, an underfill material 100 is dispensed into the gaps between the dies 68 and the interconnect structure 76. The underfill material 100 may extend up along sidewalls of the dies 68A and the dies 68B. The underfill material 100 may be any acceptable material, such as a polymer, epoxy, molding underfill, or the like. The underfill material 100 may be formed by a capillary flow process after the dies 68 are attached, or may be formed by a suitable deposition method before the dies 68 are attached.

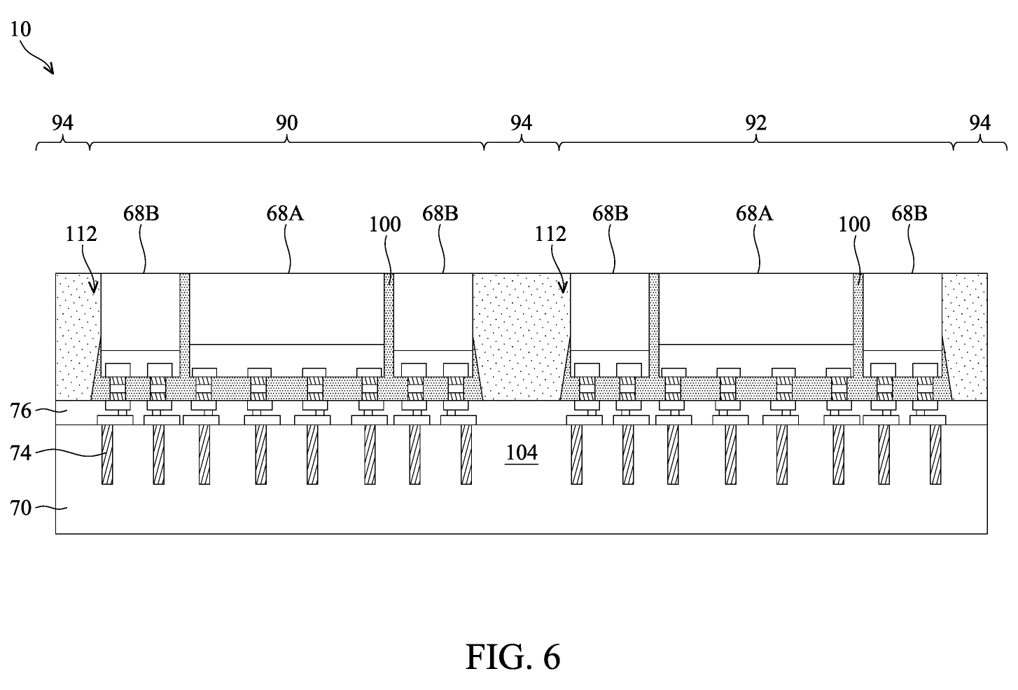

In FIG. 6, an encapsulant 112 is formed on the various components. The encapsulant 112 may be a molding compound, epoxy, or the like, and may be applied by compression molding, transfer molding, or the like. A curing step is performed to cure the encapsulant 112, such as a thermal curing, an Ultra-Violet (UV) curing, or the like. In some embodiments, the dies 68 are buried in the encapsulant 112, and after the curing of the encapsulant 112, a planarization step, such as a grinding, may be performed to remove excess portions of the encapsulant 112, which excess portions are over top surfaces of the dies 68. Accordingly, top surfaces of dies 68 are exposed, and are level with a top surface of the encapsulant 112. In some embodiments, the dies 68B may be different heights from the dies 68A, and the dies 68B will still be covered by the encapsulant 112 after the planarization step.

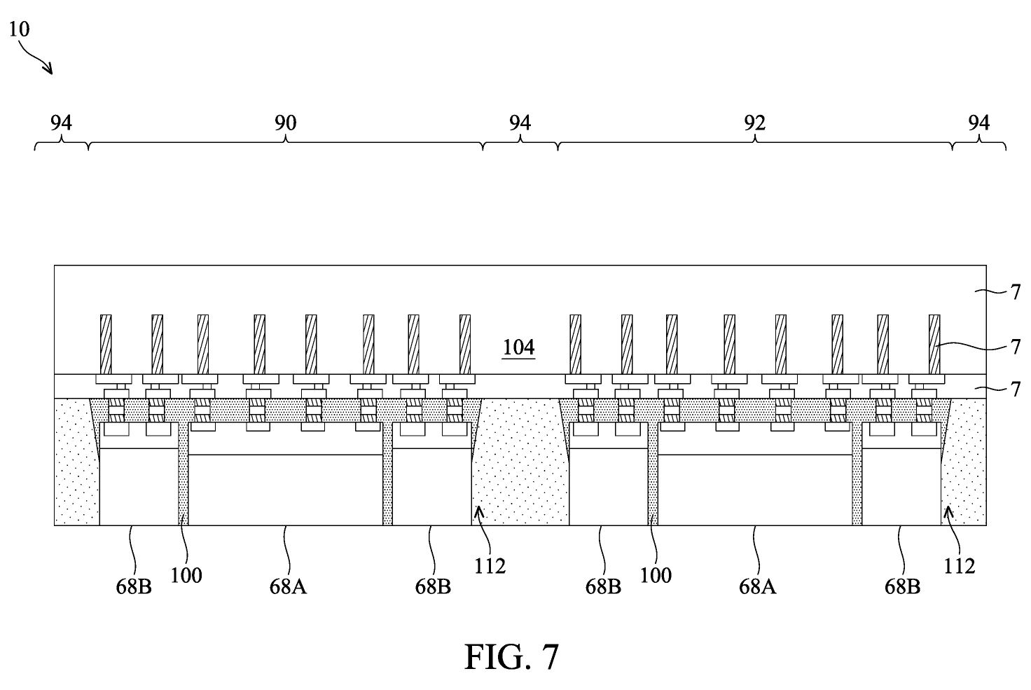

FIGS. 7 -10 illustrate the formation of the second side of components 96. In FIG. 7, the structure of FIG. 6 is flipped over to prepare for the formation of the second side of components 96. Although not shown, the structure may be placed on carrier or support structure for the process of FIGS. 7 -10.

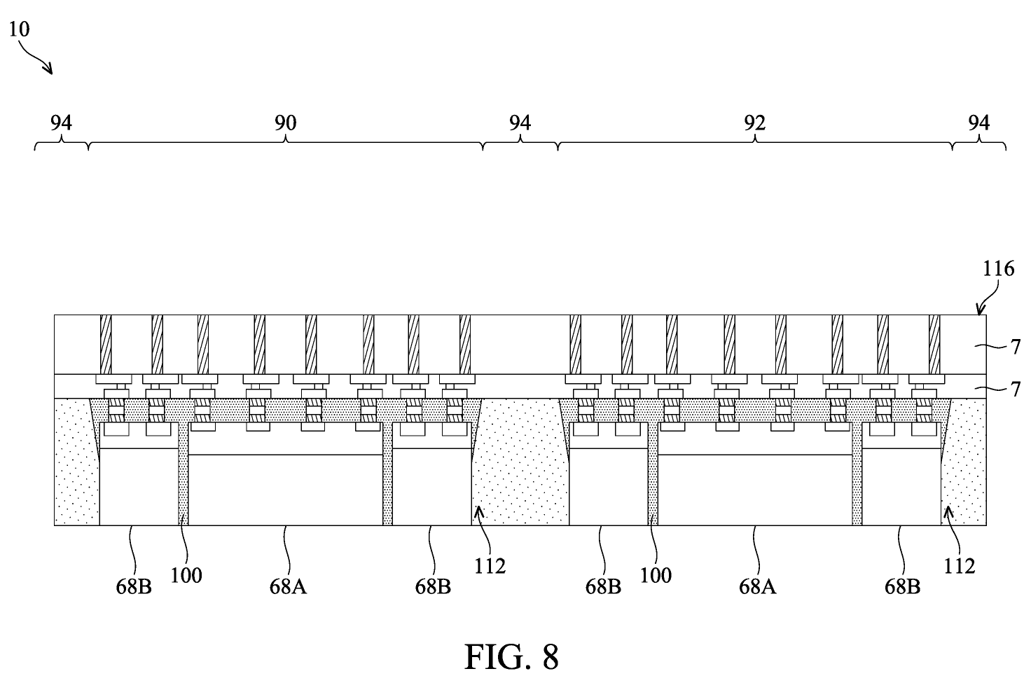

In FIG. 8, a thinning process is performed on the second side of the substrate 70 to thin the substrate 70 until TVs 74 are exposed. The thinning process may include an etching process, a grinding process, the like, or a combination thereof, applied to a second surface 116 of the substrate 70.

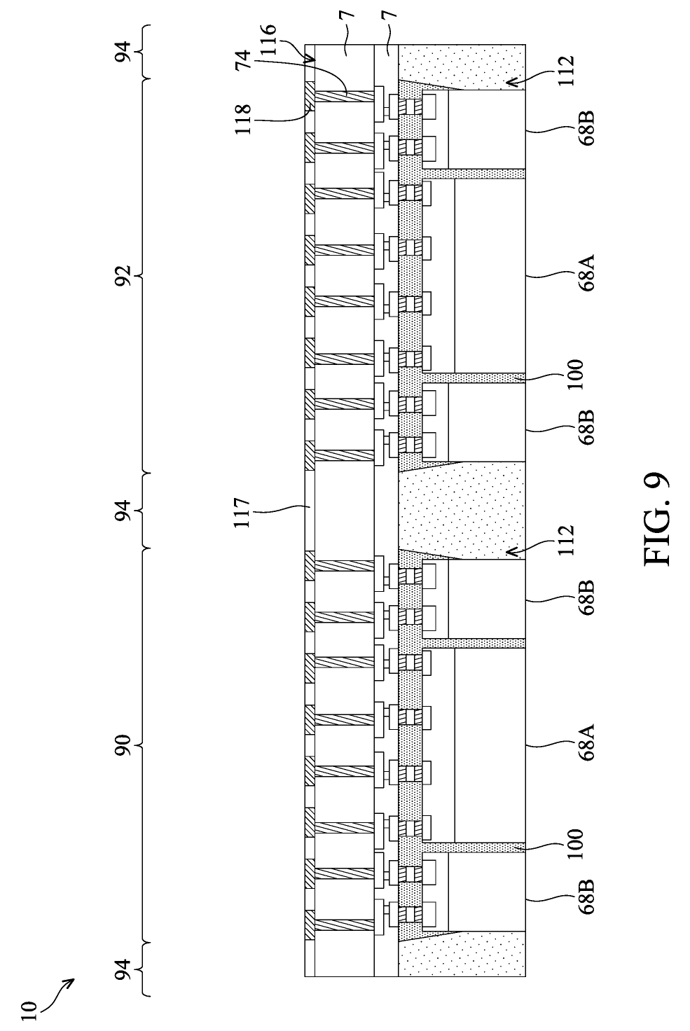

In FIG. 9, a redistribution structure is formed on the second surface 116 of the substrate 70, and is used to electrically connect the TVs 74 together and/or to external devices. The redistribution structure includes a dielectric layer 117 and metallization patterns 118 in and/or on the dielectric layer 117. The metallization patterns may comprise vias and/or traces to interconnect TVs 74 together and/or to an external device. The metallization patterns 118 are sometimes referred to as Redistribution Lines (RDLs). The dielectric layer 117 may comprise silicon oxide, silicon nitride, silicon carbide, silicon oxynitride, low-K dielectric material, such as PSG, BPSG, FSG, SiOₓC_{y}, Spin-On-Glass, Spin-On-Polymers, silicon carbon material, compounds thereof, composites thereof, combinations thereof, or the like. The dielectric layer 117 may be deposited by any suitable method known in the art, such as spinning, CVD, PECVD, HDP-CVD, or the like. The metallization patterns 118 may be formed in the dielectric layer 117, for example, by using photolithography techniques to deposit and pattern a photoresist material on the dielectric layer 117 to expose portions of the dielectric layer 117 that are to become the metallization pattern 118. An etch process, such as an anisotropic dry etch process, may be used to create openings in the dielectric layer 117 corresponding to the exposed portions of the dielectric layer 117. A seed layer (not separately illustrated) is formed over the exposed surfaces of the dielectric layer 117 and in the openings. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization patterns 118. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material form the metallization patterns 118.

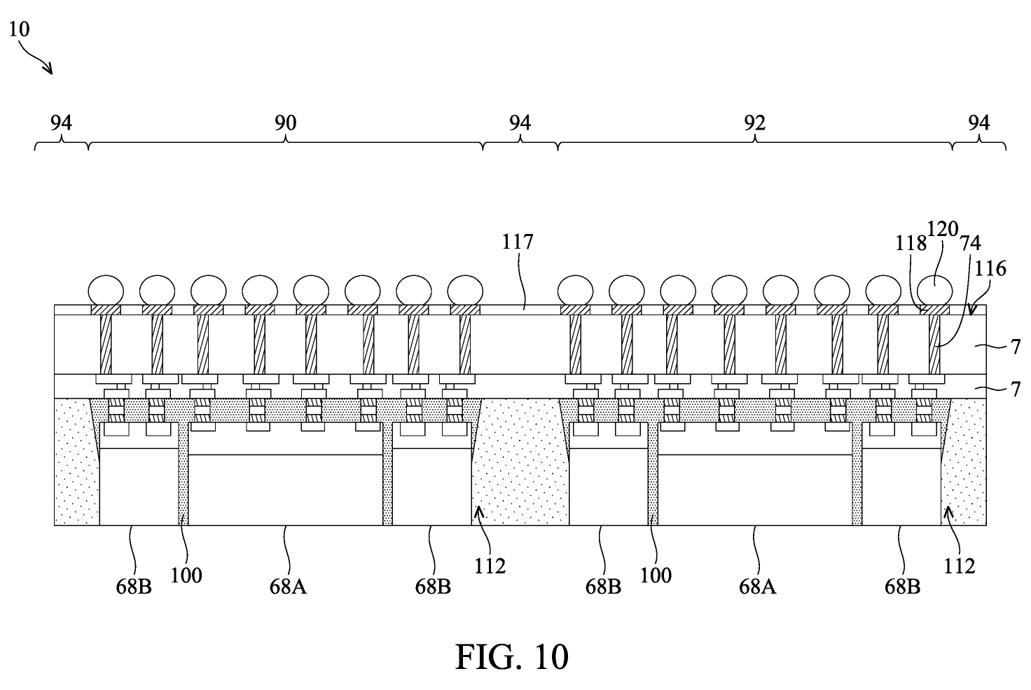

In FIG. 10, electrical connectors 120 are formed on the metallization patterns 118 and are electrically coupled to TVs 74. The electrical connectors 120 are formed at the top surface of the redistribution structure on the metallization patterns 118. In some embodiments, the metallization patterns 118 include UBMs. The electrical connectors 120 can be formed on the UBMs.

In some embodiments, the electrical connectors 120 are solder balls and/or bumps, such as ball grid array (BGA) balls, C4 micro bumps, ENIG formed bumps, ENEPIG formed bumps, or the like. The electrical connectors 120 may include a conductive material such as solder, copper, aluminum, gold, nickel, silver, palladium, tin, the like, or a combination thereof. In some embodiments, the electrical connectors 120 are formed by initially forming a layer of solder through methods such as evaporation, electroplating, printing, solder transfer, ball placement, or the like. Once a layer of solder has been formed on the structure, a reflow may be performed in order to shape the material into the desired bump shapes. In another embodiment, the electrical connectors 120 are metal pillars (such as a copper pillar) formed by a sputtering, printing, electro plating, electroless plating, CVD, or the like. The metal pillars may be solder free and have substantially vertical sidewalls. In some embodiments, a metal cap layer (not shown) is formed on the top of the metal pillar connectors 120. The metal cap layer may include nickel, tin, tin-lead, gold, silver, palladium, indium, nickel-palladium-gold, nickel-gold, the like, or a combination thereof and may be formed by a plating process.

The electrical connectors 120 will be used to bond to an additional electrical component, which may be a semiconductor substrate, a package substrate, a Printed Circuit Board (PCB), or the like (see FIG. 12).

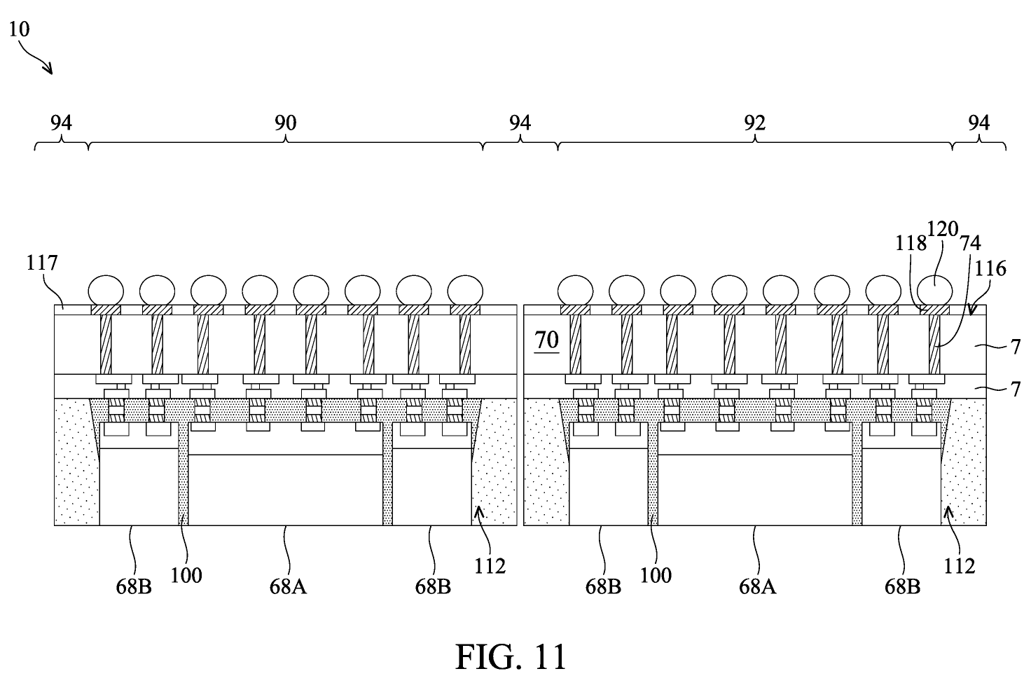

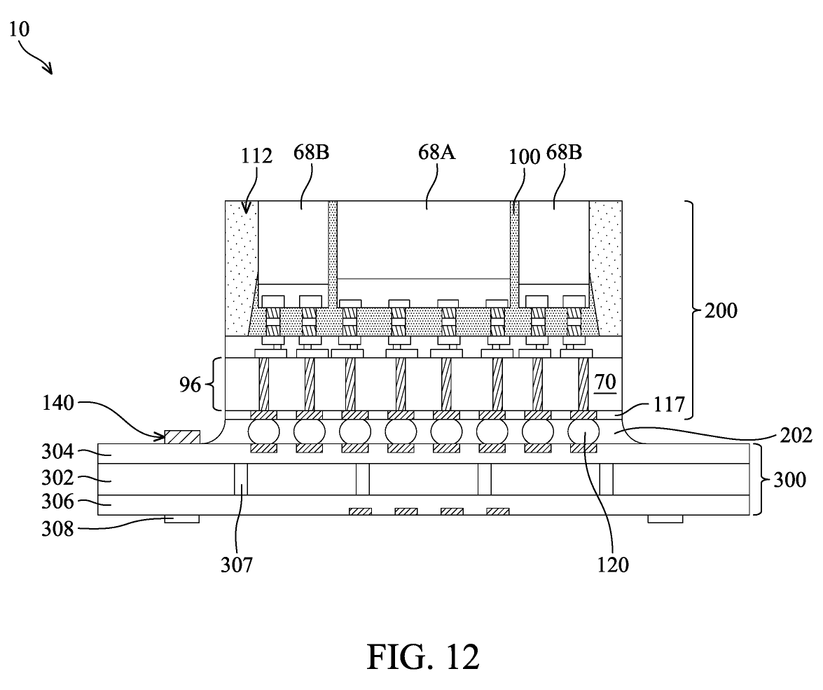

In FIG. 11, components 96 are singulated between adjacent regions 90 and 92 along scribe line regions 94 to form package components 200 comprising, among other things, a die 68A, a component 96, and dies 68B. The singulation may be by sawing, dicing, or the like.

FIG. 12 illustrates the attachment of a package component 200 on a substrate 300. Electrical connectors 120 are aligned to, and are put against, bond pads of the substrate 300. The electrical connectors 120 may be reflowed to create a bond between the substrate 300 and the component 96.

The substrate 300 may be a package substrate, or the like, and may comprise, for example, an organic substrate, a ceramic substrate, a silicon substrate, or the like. Before being attached to the package component 200, the substrate 300 may be processed according to applicable manufacturing processes to form redistribution structures in the substrate 300. For example, the substrate 300 includes a substrate core 302. The substrate core 302 may be formed of glass fiber, resin, filler, other materials, and/or combinations thereof. The substrate core 302 may be formed of organic and/or inorganic materials. In some embodiments, the substrate core 302 includes one or more passive components (not shown) embedded inside. Alternatively, the substrate core 302 may comprise other materials or components. Conductive vias 307 may be formed extending through the substrate core 302. The conductive vias 307 may comprise a conductive material such as copper, a copper alloy, or other conductors, and may include a barrier layer, liner, seed layer, and/or a fill material, in some embodiments. The conductive vias 307 provide vertical electrical connections from one side of the substrate core 302 to the other side of the substrate core 302. For example, some of the conductive vias 307 are coupled between conductive features at one side of the substrate core 302 and conductive features at an opposite side of the substrate core 302. Holes for the conductive vias 307 may be formed using a drilling process, photolithography techniques, a laser process, or other methods, as examples, and the holes of the conductive vias 307 are then filled with conductive material. In some embodiments, the conductive vias 307 are hollow conductive through vias having centers that are filled with an insulating material. Redistribution structures 304 and 306 are formed on opposing sides of the substrate core 302. The redistribution structures 304 and 306 are electrically coupled by the conductive vias 307, and may fan-out electrical signals. The redistribution structures 304 and 306 each include dielectric layers and metallization patterns. The redistribution structure 304 may be attached to the package component 200 by the electrical connectors 120. A side of the substrate 300 comprising an exposed surface of the redistribution structure 304 may also be referred to as the front side of the substrate 300. A side of the substrate 300 comprising an exposed surface of the redistribution structure 306 may also be referred to as the back side of the substrate 300.

Referring further to FIG. 12, land grid array (LGA) pads 308 may be disposed on the back side of the substrate 300 (e.g., on a surface of the redistribution structure 306). The LGA pads 308 may comprise flat, metallic pads (e.g., comprising copper, or the like) that serve as contact points for making electrical connections between the package structure 10 and other external devices or package components.

An underfill material 202 can be dispensed between the package component 200 and the substrate 300 and surrounding the electrical connectors 120. The underfill material 202 may be any acceptable material, such as a polymer, epoxy, molding underfill, or the like.

Additionally, one or more surface devices 140 may be connected to the substrate 300. The surface devices 140 may be used to provide additional functionality or programming to the package component 200, or the package as a whole. In an embodiment, the surface devices 140 may include surface mount devices (SMDs) or integrated passive devices (IPDs) that include passive devices such as resistors, inductors, capacitors, jumpers, combinations of these, or the like that are desired to be connected to and utilized in conjunction with package component 200, or other parts of the package. The surface devices 140 may be placed on a first major surface of the substrate 300, an opposing major surface of the substrate 300, or both, according to various embodiments.

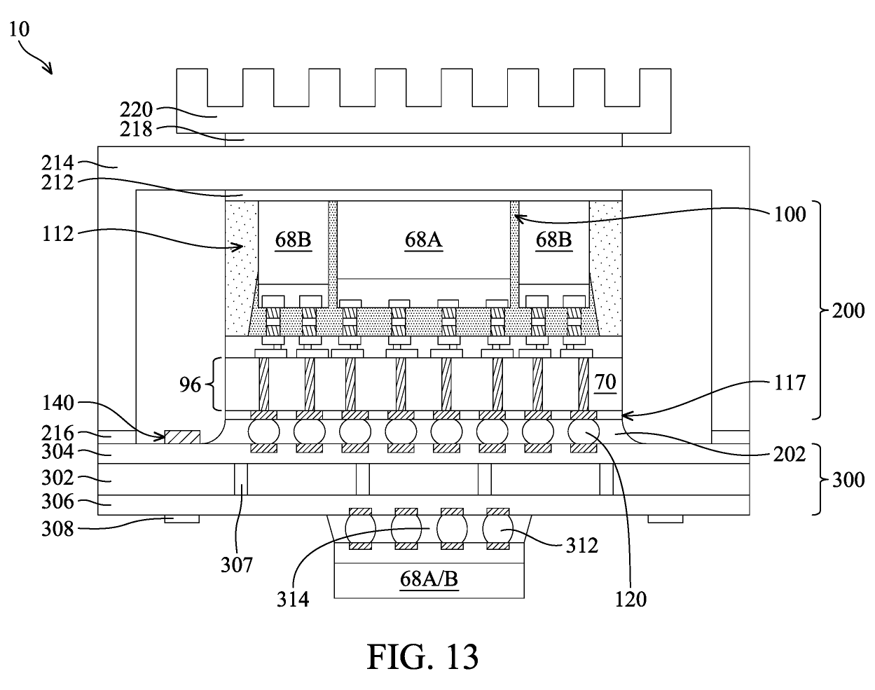

In FIG. 13, an adhesive material 216 is dispensed on the substrate 300. The adhesive material 216 may comprise any material suitable for sealing a component such as a heat spreader 214 onto the substrate 300, such as epoxies, urethane, polyurethane, silicone elastomers, and the like. The adhesive material 216 may be dispensed to an outer portion or a periphery or edges of the substrate 300. The heat spreader 214 may comprise a thermal lid or thermal ring. In addition, a thermal interface material (TIM) 212 is applied to a top surface of the package component 200, such as on top surfaces of the die 68A and 68B, as well as top surfaces of the underfill material 100. The TIM 212 may include but is not limited to, graphite, polymer based gel, thermal grease, phase change material, liquid bonding material, metal filled polymer matrix, and solder alloys of lead, tin, indium, silver, copper, bismuth, and the like (most preferred is indium or lead/tin alloy). If the TIM 212 is a solid, it may be heated to a temperature at which it undergoes a solid to liquid transition and then may be applied in liquid form to the top surface of package component 200.

Further referring to FIG. 13, the heat spreader 214 is placed on the substrate 300 such that the heat spreader surrounds the package component 200, and is also disposed over the package component 200. The heat spreader 214 may be formed of a material with high thermal conductivity, such as a metal, such as copper, steel, iron, or the like. The heat spreader 214 protects the package component 200. The heat spreader 214 is coupled to the package component 200 by way of the TIM 212. After the heat spreader 214 is placed on the substrate 300, a suitable curing process may be performed that cures the adhesive material 216 to enable secure attachment of the heat spreader 214 to the substrate 300.

After the heat spreader 214 is attached to the substrate 300, an optional cooling device 220 may be coupled to a top surface of the heat spreader 214 by way of a TIM 218. The TIM 218 may comprise similar materials and may be applied in a similar manner as was described previously for the TIM 212. The cooling device 220 is placed on the heat spreader 214, wherein the cooling device 220 is coupled to the heat spreader 214 by way of the TIM 218. The cooling device 220 may also be referred to subsequently as a heat dissipation structure. In some embodiments, the cooling device 220 may be any suitable device that can be used to dissipate heat. For example, in an embodiment, the cooling device 220 may be a heat pipe cooling device, an air (fan) cooling device, or the like. The cooling device may not be shown in subsequent figures.

Either before or after the heat spreader 214 is attached to the substrate 300, electrical connectors 312 are formed on bond pads of the redistribution structure 306. In some embodiments, the electrical connectors 312 are solder balls and/or bumps, such as ball grid array (BGA) balls, C4 micro bumps, or the like. The electrical connectors 312 may include a conductive material such as solder, copper, aluminum, gold, nickel, silver, palladium, tin, the like, or a combination thereof. In some embodiments, the electrical connectors 312 are formed by initially forming a layer of solder through methods such as evaporation, electroplating, printing, solder transfer, ball placement, or the like. Once a layer of solder has been formed on the structure, a reflow may be performed in order to shape the material into the desired bump shapes.

After the formation of the electrical connectors 312, a die 68 (which may comprise a die 68A or a die 68B that were described previously) is attached to the back side of the substrate 300 using the electrical connectors 312. The die 68A/B coupled to the back side of the substrate 300 is electrically coupled to the other dies 68A/B of the package component 200 through the substrate 300, the TVs 74, and the electrical connectors 120.

The bonding between the die 68 on the back side of the substrate 300 and the substrate 300 may be a solder bonding. In an embodiment, the die 68 is bonded to the bond pads of the redistribution structure 306 on the back side of the substrate 300 by a reflow process. During this reflow process, the electrical connectors 312 are in contact to physically and electrically couple the die 68A/B to the substrate 300.

An underfill material 314 can be dispensed between the substrate 300 and the die 68A/B that is coupled to the backside of the substrate 300. The underfill material 314 may surround the electrical connectors 312. The underfill material 314 may be any acceptable material, such as a polymer, epoxy, molding underfill, or the like.

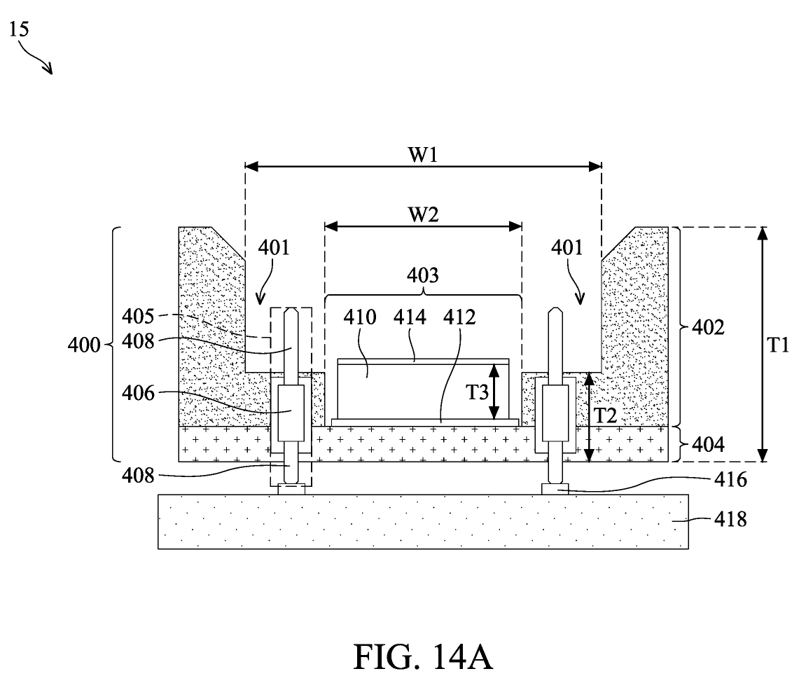

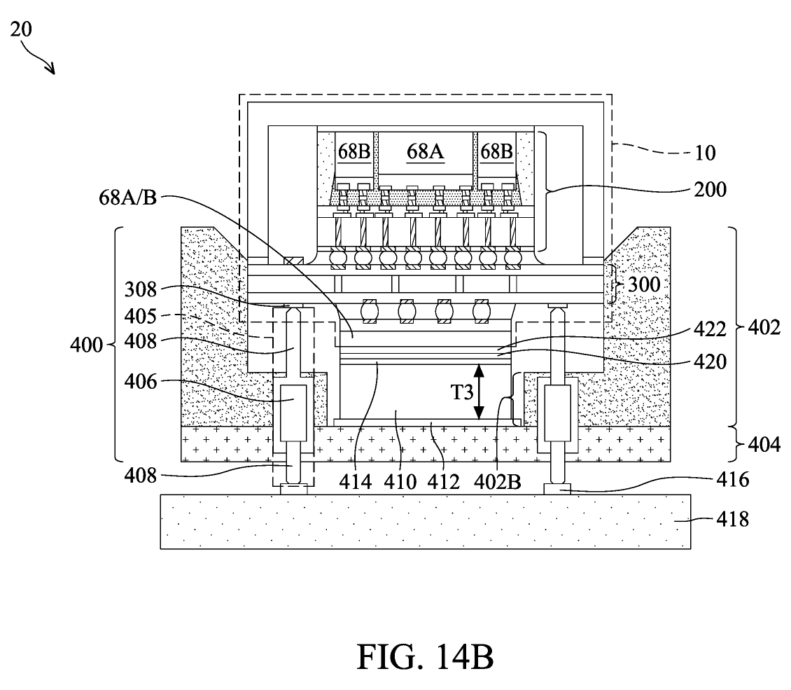

FIG. 14A illustrates a component 15 that is used to establish temporary electrical connections between the package structure 10 shown previously in FIG. 13 and specific test points on a printed circuit board (PCB) 418. After the temporary electrical connections are established, the electrical characteristics, functionality, and performance of the package structure 10 can be assessed and tested. The component 15 may comprise a fixture 400 (also referred to as a socket module) that comprises a top portion 402 (also referred to as a top guide plate), a bottom portion 404 (also referred to as a bottom guide plate), and socket pins 405 that extend through the top portion 402 and the bottom portion 404 of the fixture 400. The top portion 402 and the bottom portion 404 may comprise a machinable ceramic, vespel, aluminum nitride, polyetheretherketone (PEEK) engineering plastic, teflon, or the like. In an embodiment, a total thickness T1 of the top portion 402 and the bottom portion 404 may be in a range from 5.5 mm to 8 mm. Each of the socket pins 405 may comprise a moveable bottom plunger 408 that extends below the bottom surface of the fixture 400 and that is inserted into a respective hole 416 in the PCB 418 that is aligned with an intended contact point (e.g., contact pad) in the PCB 418. Each socket pin 405 may also comprise a moveable top plunger 408. These contact points may correspond to test points, programming interfaces, or other areas where temporary electrical connections are required. After the bottom plunger 408 of each socket pin 405 is inserted into a respective hole 416 in the PCB, the socket pin 405 is in physical and electrical contact with the contact point. Each socket pin 405 further comprises a housing 406 (which may also be referred to as a barrel) disposed between the top plunger 408 and the bottom plunger 408, wherein the housing 406 is disposed within the fixture 400. A spring mechanism is disposed in the housing 406, and this spring mechanism allows the socket pin 405 to compress or retract (e.g., through vertical movement of the top plunger 408 and/or the bottom plunger 408) when pressure is applied and return to its extended position when the force is removed. In an embodiment, the socket pin 405 does not allow for lateral movement of the socket pin 405, and a gap may surround the sidewalls of the housing 406 (e.g., a space may be disposed between sidewalls of the housing 406 and the fixture 400. In an embodiment, the housing 406, the top plunger 408 and the bottom plunger 408 may comprise brass, copper, or the like, on which a thin layer of nickel, rhodium, gold, bronze or alloy is formed.

The top portion 402 of the fixture 400 may comprise a first cavity 401 that extends partially through the top portion 402 of the fixture 400. A second cavity 403 is disposed in the remainder of the top portion 402 of the fixture 400. For example, the second cavity 403 may be disposed within the bottom surface of the first cavity 401. The remainder of the top portion 402 of the fixture 400 and the bottom portion 404 of the fixture 400 may have a total thickness T2 that is in a range from 1.5 mm to 4 mm. Advantages may be achieved by the top portion 402 and the bottom portion 404 having the total thickness T1 that is in the range from 5.5 mm to8mm, and the remainder of the top portion 402 of the fixture 400 and the bottom portion 404 of the fixture 400 having the total thickness T2 that is in the range from 1.5 mm to 4mm. These include allowing the first cavity 401 to have an adequate depth to adequately secure the package structure 10 when the package structure 10 is inserted into and positioned within the first cavity 401 as shown subsequently in FIG. 14B. For example, the top portion 402 and the bottom portion 404 having the total thickness T1 that is smaller than 5.5 mm, or the remainder of the top portion 402 of the fixture 400 and the bottom portion 404 of the fixture 400 having the total thickness T2 that is greater than 4mm may lead to the package structure 10 being inadequately secured in the first cavity 401, which may lead to reliability issues and degraded performance during operation. A width W1 of the first cavity 401 may be greater than a width W2 of the second cavity 403. A thermoelectric cooling (TEC) module 410 (also referred to as a peltier device or thermoelectric cooler), is disposed in the second cavity 403, wherein the TEC module 410 is attached to a bottom surface of the second cavity 403 using an adhesive layer 412 (e.g., a die attach film, or the like). The TEC module 410, may be a solid-state electronic component designed to regulate temperature by harnessing the peltier effect. The TEC module 410 may comprise multiple semiconductor elements that are composed of n-type and p-type materials, arranged in a series and sandwiched between ceramic substrates. When a direct electric current is applied to the semiconductor junctions (e.g., where an n-type material contacts a p-type material), heat is absorbed on one side (cooling side) and released on the other (heating side). This temperature differential enables the TEC module 410 to cool or heat specific areas, depending on the direction of the current. In an embodiment, a thickness T3 of the TEC module 410 may be in a range from 1 mm to 3 mm. In an embodiment, a ratio of an area of a top surface of the TEC module 410 to an area of a bottom surface of the substrate 300 (e.g., shown subsequently in FIG. 14B) is in a range from 50 percent to 80 percent. In an embodiment, a top surface of the TEC module 410 is higher than the bottom surface of the first cavity 401. A metal layer 414 may be disposed on a top surface of the TEC module 410. In an embodiment, the metal layer 414 may comprise titanium, copper, nickel vanadium, gold, a combination thereof, or the like.

In an embodiment, a top plunger 408 of each socket pin 405 may protrude above the bottom surface of the first cavity 401. In an embodiment, a portion of the top plunger 408 of each socket pin 405 may be higher than the top surface of the TEC module 410 that is disposed within the second cavity. In an embodiment, the portion of the top plunger 408 of each socket pin 405 may be higher than a top surface of the metal layer 414.

The electrical characteristics, functionality, and performance of the package structure 10 may be assessed and tested by establishing temporary electrical connections (as shown subsequently in FIG. 14B) between the package structure 10 and specific test points on the PCB 418 (e.g., as shown subsequently in FIG. 14B) by way of the fixture 400. The bottom plungers 408 of each socket pin 405 may be inserted into respective holes 416 in the PCB 418 that are aligned with respective contact points (e.g., contact pads) in the PCB 418. After the bottom plunger 408 of each socket pin 405 is inserted into a respective hole 416 in the PCB 418, the socket pin 405 is in physical and electrical contact with the contact point (e.g., a contact pad).

The PCB 418 may comprise non-conductive substrate materials such as fiberglass-reinforced epoxy (FR-4), ceramics, or the like. The PCB 418 may comprise thin layers of copper foil laminated onto its surface, to define conducting traces that function as electrical pathways. Components may be mounted onto the PCB 418 through surface mount technology (SMT).

In an embodiment, the PCB 418 is used for testing the package structure 10, and is coupled to the fixture 400 to form the component 15. The PCB 418 provides an interface for testing the package structure 10, and comprises contact points, connectors, holes 416 (e.g., sockets) that align with the specific layout and configuration of the package structure 10 being tested. The PCB 418 may be dedicated to the testing stage and may be used to facilitate the application of electrical signals, measurements, and tests to assess the performance of the package structure 10.

In other embodiments, the PCB 418 and the fixture 400 are permanently assembled into the component 15 during manufacturing, where the PCB 418 serves functional requirements as part of a final electronic product (e.g., combined package structure 20 shown subsequently in FIG. 14B). The PCB 418 may comprise electronic components, circuits, and connections necessary for the intended operation of the combined package structure 20. This includes microprocessors, memory, sensors, and other components. In addition, The PCB 418 may also integrate various other devices and packages, expanding its functionality and accommodating diverse electronic components beyond the combined package structure 20.

In FIG. 14B, the package structure 10 is then inserted into and positioned within the first cavity 401 of the fixture 400, wherein a portion of the package structure 10 is secured between sidewalls of the first cavity 401 to ensure proper alignment of the top plungers 408 with respective LGA pads 308 on the back side of the substrate 300 of the package structure 10. After the package structure 10 is inserted into and positioned within the first cavity 401 of the fixture 400, a portion of the package structure 10 may also protrude above top surfaces of the fixture 400 and above the first cavity 401. The fixture 400 is designed to securely hold and support the package structure 10 in place during electrical testing and prevent lateral movement of the package structure 10 during the electrical testing. After the package structure is positioned within the first cavity 401 of the fixture 400, each top plunger 408 of each socket pin 405 is in physical and electrical contact with a respective LGA pad 308 on the substrate 300 ensuring electrical connection between the package structure 10 and the PCB 418 through the socket pins 405. The spring mechanism of each socket pin 405 allows the socket pin 405 to compress (e.g., through vertical movement of the top plunger 408 and/or the bottom plunger 408) when the package structure 10 is inserted into the first cavity 401 and pressure is applied to the socket pin 405. In addition, after the package structure 10 is positioned within the first cavity 401 of the fixture 400, the TEC module 410 is in physical contact with a bottom surface of the die 68A/B, the die 68A/B being coupled to the back side of the substrate 300 by way of a thermal interface material (TIM) 420 disposed between the TEC module 410 and the die 68A/B. The TIM 420 may comprise similar materials and may be applied in a similar manner as was described previously in FIG. 13 for the TIM 212 and the TIM 218. For example, a metal layer 422 may be disposed on a bottom surface of the die 68A/B that is coupled to the back side of the substrate 300. In an embodiment, the metal layer 422 may comprise titanium, copper, nickel vanadium, gold, a combination thereof, or the like. The TIM 420 may be applied to a top surface of the metal layer 414 and/or a bottom surface of the metal layer 422. After the package structure 10 is positioned within the first cavity 401 of the fixture 400, the die 68A/68B is coupled to the TEC module 410 by way of the TIM 420. In other embodiments, the metal layer 422 and the metal layer 414 are not present, and the TEC module 410 is coupled directly to the die 68A/68B by way of the TIM 420.

After the package structure 10 is inserted and positioned within the first cavity 401 of the fixture 400, the electrical testing of the package structure 10 is then performed. During the electrical testing, electrical signals, test patterns, or specific stimuli are applied to the package structure 10 through the PCB 418 and the fixture 400 (e.g., through the socket pins 405), and the corresponding responses are carefully monitored. In this way, the package structure 10’s functionality, reliability, and performance is assessed. During the electrical testing, a direct electric current may be applied to the semiconductor junctions (e.g., where an n-type material contacts a p-type material) of the TEC module 410, to facilitate the absorbing of heat on a first side (e.g., a cooling side) of the TEC module 410 that faces the package structure 10, and the releasing of heat on a second side (e.g., a heating side) that is on an opposite side of the TEC module 410 as the first side of the TEC module 410. This temperature differential enables the TEC module 410 to cool the package structure 10 as the electrical testing is being performed.

After the electrical testing of the package structure 10 is performed, the package structure 10 may be removed from the first cavity 401 of the fixture 400, thereby de-coupling the component 15 from the package structure 10. In an embodiment, further processes may then be performed on the package structure 10. The spring mechanism of each socket pin 405 allows the socket pin 405 retract (e.g., through vertical movement of the top plunger 408 and/or the bottom plunger 408) and return to its extended position when the package structure 10 is removed from the first cavity 401 and pressure on the socket pin 405 is reduced.

Advantages may be achieved as a result of inserting and positioning the package structure 10 within the first cavity 401 of the fixture 400, such that electrical connection is established between the package structure 10 and the PCB 418 through the socket pins 405, and the TEC module 410 that is disposed in the second cavity 403 of the fixture 400 is in physical and thermal contact with a bottom surface of the die 68A/B, the die 68A/B being coupled to the back side of the substrate 300 by way of the TIM 420 disposed between the TEC module 410 and the die 68A/B. In other embodiments, the TEC module 410 is in thermal contact with the die 68A/B by way of the metal layer 414, TIM 420, and the metal layer 422. A direct electric current may be applied to the semiconductor junctions (e.g., where an n-type material contacts a p-type material) of the TEC module 410 during electrical testing of the package structure 10. These advantages include enhanced cooling of the package structure 10 (e.g., including the die 68A/B on the back side of the substrate 300) from the back side of the substrate 300 during electrical testing of the package structure 10. This enhanced cooling may allow the bonding and utilization of a greater number of dies in the package structure 10 on both the front side and the back side of the substrate 300, since the enhanced cooling may adequately accommodate the additional heat generated by an increased number of dies. In addition, the enhanced cooling of the package structure 10 (e.g., including the die 68A/B on the backside of the substrate 300) from the back side of the substrate 300 efficiently eliminates heat traps and mitigates hot spots during electrical testing, which results in improved thermal management and overall temperature control of the package structure 10. This further allows for power to be delivered to the package structure 10 from the back side of the substrate 300 without the formation of hot spots and heat traps within the package structure 10.

In other embodiments, the PCB 418 serves functional requirements as part of a final electronic product and the PCB 418 and the fixture 400 are permanently assembled into the component 15, which is then coupled to the package structure 10 to form the combined package structure 20 (as shown in FIG. 14B). The PCB 418 may comprise electronic components, circuits, and connections necessary for the intended operation of the combined package structure 20. This includes microprocessors, memory, sensors, and other components. In addition, The PCB 418 may also integrate various other devices and packages, expanding its functionality and accommodating diverse electronic components beyond the combined package structure 20. To couple the package structure 10 to the component 15, solder paste, (e.g., a mixture of tiny solder particles and flux) may be applied to the LGA pads 308 and/or on the top plungers 408. This solder paste is strategically placed in areas where the electrical connection is desired. The package structure 10 may then be inserted into and positioned within the first cavity 401 of the fixture 400, wherein a portion of the package structure 10 is secured between sidewalls of the first cavity 401 to ensure proper alignment of the top plungers 408 with respective LGA pads 308 on the back side of the substrate 300 of the package structure 10. After the package structure 10 is positioned within the first cavity 401 of the fixture 400, each top plunger 408 of each socket pin 405 is in physical and electrical contact with a respective LGA pad 308 on the substrate 300. The combined package structure 20 may then be subjected to heat through a reflow process (e.g., a reflow soldering process), or the like. This causes the solder paste to melt, facilitating the formation of a solder joint between each of the socket pins 405 and a respective LGA pad 308. In this way the package structure 10 and the component 15 are coupled together to form the combined package structure 20. In addition, after the package structure 10 is positioned within the first cavity 401 of the fixture 400 and coupled to the socket pins 405, the TEC module 410 is in physical contact and coupled to the bottom surface of the die 68A/B on the back side of the substrate 300 by way of the TIM 420 disposed between the TEC module 410 and the die 68A/B, in a similar manner as was described above.

During operation of the combined package structure 20, a direct electric current may be applied to the semiconductor junctions (e.g., where an n-type material contacts a p-type material) of the TEC module 410, to facilitate the absorbing of heat on a first side (e.g., a cooling side) of the TEC module 410 that faces the package structure 10, and the releasing of heat on a second side (e.g., a heating side) that is on an opposite side of the TEC module 410 as the first side of the TEC module 10. This temperature differential enables the TEC module 410 to cool the package structure 10 as the combined package structure 20 is in operation.

Advantages may be achieved as a result of inserting and positioning the package structure 10 within the first cavity 401 of the fixture 400, and coupling the package structure 10 to the fixture 400 to form the combined package structure 20, such that electrical connection is established between the package structure 10 and the PCB 418 through the socket pins 405, and the TEC module 410 that is disposed in the second cavity 403 of the fixture 400 is in physical contact with a bottom surface of the die 68A/B, the die 68A/B being coupled to the back side of the substrate 300 by way of the TIM 420 disposed between the TEC module 410 and the die 68A/B. In other embodiments, the TEC module 410 is in thermal contact with the die 68A/B by way of the metal layer 414, TIM 420, and the metal layer 422. A direct electric current may be applied to the semiconductor junctions (e.g., where an n-type material contacts a p-type material) of the TEC module 410. These advantages include enhanced cooling of the package structure 10 (e.g., including the die 68A/B on the back side of the substrate 300) from the back side of the substrate 300 when the combined package structure 20 is in operation. This enhanced cooling may allow the bonding and utilization of a greater number of dies in the package structure 10 on both the front side and the back side of the substrate 300, since the enhanced cooling may adequately accommodate the additional heat generated by an increased number of dies. In addition, the enhanced cooling of the package structure 10 (e.g., including the die 68A/B on the backside of the substrate 300) from the back side of the substrate 300 efficiently eliminates heat traps and mitigates hot spots during operation of the combined package structure 20, which results in improved thermal management and overall temperature control of the package structure 10. This further allows for power to be delivered to the package structure 10 from the back side of the substrate 300 without the formation of hot spots and heat traps within the package structure 10.

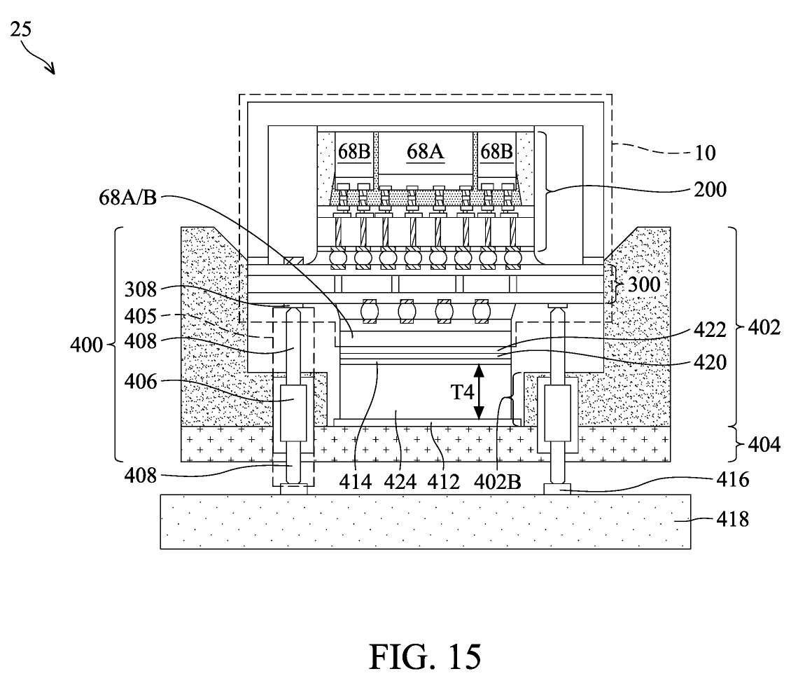

FIG. 15 illustrates a structure of an alternative embodiment after the package structure 10 is positioned within the first cavity 401 of the fixture 400. Unless specified otherwise, like reference numerals in this embodiment (and subsequently discussed embodiments) represent like components in the embodiment shown in FIGS. 1 -14B formed by like processes. Accordingly, the process steps and applicable materials may not be repeated herein. The structure shown in FIG. 15 differs from the structure shown previously in FIG. 14B in that in the structure shown in FIG. 15, the TEC module 410 is not disposed in the second cavity 403. Instead of the TEC module 410, a metal block 424 (e.g., a copper slug) is disposed in the second cavity 403, wherein the metal block 424 is attached to a bottom surface of the second cavity 403 using an adhesive layer 412 (e.g., a die attach film, or the like). The metal block 424 may comprise copper, silver, or the like, and may have a thickness T4 that is in a range from 1 mm to 3 mm. After the package structure 10 is positioned within the first cavity 401 of the fixture 400, the metal block 424 is in physical contact with a bottom surface of the die 68A/B, the die 68A/B being coupled to the back side of the substrate 300 by way of the TIM 420 disposed between the metal block 424 and the die 68A/B. In an embodiment, the metal layer 414 may be disposed over the metal block 424, and the metal layer 422 may be disposed on a bottom surface of the die 68A/B, the die 68A/B being coupled to the back side of the substrate 300. The metal layer 414 may be in physical and thermal contact with the metal layer 422 by the way of the TIM 420 that is disposed between a top surface of the metal layer 414 and a bottom surface of the metal layer 422. In an embodiment, the metal layers 414 and 422 may comprise titanium, copper, nickel vanadium, gold, a combination thereof, or the like. In other embodiments, the metal layer 422 and the metal layer 414 are not present, and the TEC module 410 is coupled directly to the die 68A/68B by way of the TIM 420. The high thermal conductivity of the material of the metal block 424 allows it to quickly absorb and transfer the heat away from the package structure 10 (e.g., the die 68A/B that is coupled to the back side of the substrate 300), thereby facilitating the cooling of the package structure 10.

After the package structure 10 is inserted and positioned within the first cavity 401 of the fixture 400, the electrical testing of the package structure 10 can then be performed as described previously in FIG. 14B. During the electrical testing, the high thermal conductivity of the material of the metal block 424 allows it to quickly absorb and transfer the heat away from the package structure 10 (e.g., the die 68A/B that is coupled to the back side of the substrate 300), thereby facilitating the cooling of the package structure 10. After the electrical testing of the package structure 10 is performed, the package structure 10 may be removed from the first cavity 401 of the fixture 400 as described previously in FIG. 14B.

In other embodiments, the PCB 418 serves functional requirements as part of a final electronic product, and the PCB 418 and the fixture 400 are permanently assembled and coupled to the package structure 10 to form a combined package structure 25. The PCB 418 may comprise electronic components, circuits, and connections necessary for the intended operation of the combined package structure 25. This includes microprocessors, memory, sensors, and other components. In addition, The PCB 418 may also integrate various other devices and packages, expanding its functionality and accommodating diverse electronic components beyond the combined package structure 25. After the package structure 10 is positioned within the first cavity 401 of the fixture 400, a reflow process (similar to the reflow process described previously in FIG. 14B used to couple each of the socket pins 405 to a respective LGA pad 308) is used to facilitate the formation of a solder joint between each of the socket pins 405 and a respective LGA pad 308 on the substrate 300. In this way the package structure 10 is coupled to the fixture 400 and the substrate 300 to form the combined package structure 25. In addition, after the package structure 10 is positioned within the first cavity 401 of the fixture 400 and coupled to the socket pins 405, the metal block 424 is in physical contact and coupled to the bottom surface of the die 68A/B on the back side of the substrate 300 by way of the TIM 420 disposed between the metal block 420 and the die 68A/B, in a similar manner as was described above.

During operation of the combined package structure 25, the high thermal conductivity of the material of the metal block 424 allows it to quickly absorb and transfer the heat away from the package structure 10 (e.g., the die 68A/B that is coupled to the back side of the substrate 300), thereby facilitating the cooling of the package structure 10.

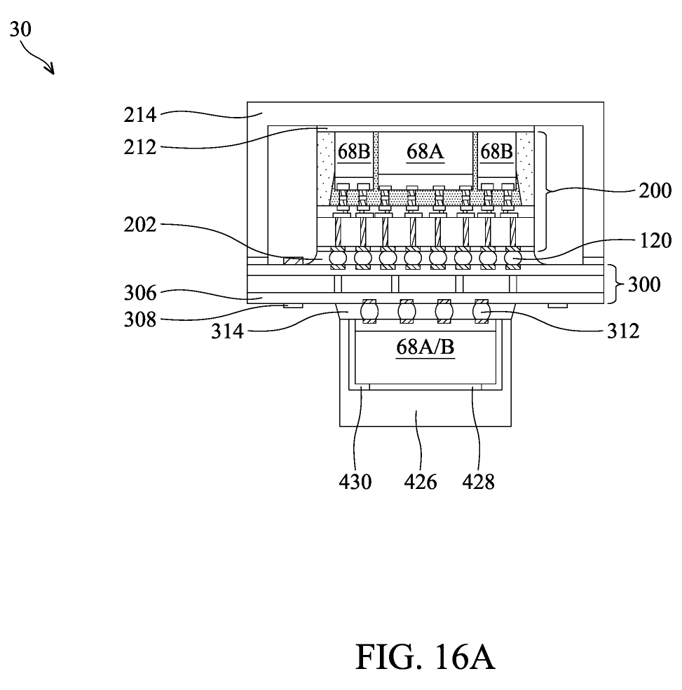

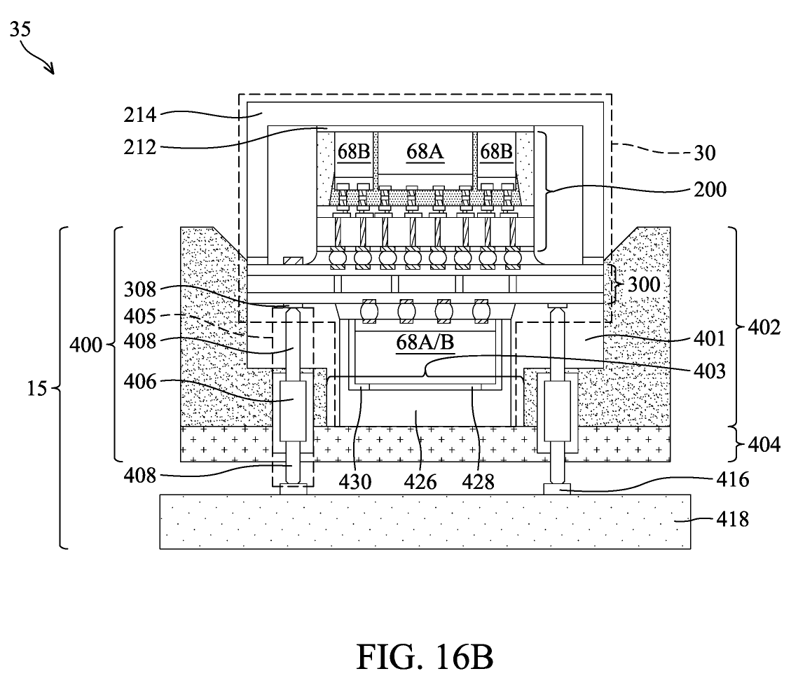

FIGS. 16A and 16B illustrate an alternative embodiment. Unless specified otherwise, like reference numerals in this embodiment (and subsequently discussed embodiments) represent like components in the embodiment shown in FIGS. 1 -15 formed by like processes. Accordingly, the process steps and applicable materials may not be repeated herein. FIG. 16A illustrates a package structure 30 that may be similar to the package structure 10 described previously in FIG. 13, except that the die 68A/B is embedded within a TEC module 426 prior to coupling the die 68A/B to the substrate 300 using the electrical connectors 312. The TEC module 426 may operate in a similar manner and be formed of similar materials as the TEC module 410 that was described previously in FIG. 14A.

The die 68A/B may be disposed within a cavity in the TEC module 426. The die 68A/B may be attached to a bottom surface and sidewalls of the cavity within the TEC module 426 through the use of an adhesive layer 430 (e.g., a die attach film) that may be disposed on sidewalls and edge portions of a bottom surface within the cavity prior to placing the die 68A/B in the cavity. In addition, a TIM 428 may be applied to a center portion of a bottom surface of the die 68A/B and/or a center portion of the bottom surface within the cavity prior to placing the die 68A/B in the cavity. The TIM 428 may comprise similar materials and may be applied in a similar manner as was described previously in FIG. 13 for the TIM 212 and the TIM 218. After placing the die 68A/B in the cavity, the die 68A/B is coupled to and embedded within the TEC module 426, wherein a top surface of the die 68A/B may be level with top surfaces of the TEC module 426.

After the embedding of the die 68A/B in the TEC module 426, the die 68A/B and the TEC module 426 are attached to the back side of the substrate 300 using the electrical connectors 312. The die 68A/B coupled to the back side of the substrate 300 is electrically coupled to the other dies 68A/B of the package component 200 through the substrate 300, the TVs 74, and the electrical connectors 120.

The bonding between the substrate 300 and the die 68A/B on the back side of the substrate 300 may be a solder bonding. In an embodiment, the die 68A/B is bonded to the bond pads of the redistribution structure 306 on the back side of the substrate 300 by a reflow process. During this reflow process, the electrical connectors 312 are in contact to physically and electrically couple the die 68A/B to the substrate 300.

An underfill material 314 can be dispensed between the substrate 300 and the die 68A/B, and between the substrate 300 and the TEC module 426 that is coupled to the backside of the substrate 300. The underfill material 314 may surround the electrical connectors 312. The underfill material 314 may be any acceptable material, such as a polymer, epoxy, molding underfill, or the like.

In an alternate embodiment, the TEC module 426 may be replaced with a metal block, wherein the metal block may comprise copper, silver, or the like. For example, the die 68A/B may be disposed within a cavity in the metal block. The die 68A/B may be attached to a bottom surface and sidewalls of the cavity within the metal block through the use of the adhesive layer 430 (e.g., a die attach film) that may be disposed on sidewalls and edge portions of a bottom surface within the cavity prior to placing the die 68A/B in the cavity. In addition, a TIM 428 may be applied to a center portion of a bottom surface of the die 68A/B and/or a center portion of the bottom surface within the cavity prior to placing the die 68A/B in the cavity.

FIG. 16B illustrates the package structure 30 being inserted into and positioned within the first cavity 401 of the fixture 400 of the component 15, wherein the component 15 shown in FIG. 16B differs from the component 15 shown previously in FIG. 14B in that the component 15 shown in the FIG. 16B does not comprise the TEC module 410 disposed in the second cavity 403 of the fixture 400. When the package structure 30 is inserted into and positioned within the first cavity 401 of the fixture 400, a portion of the package structure 30 is secured between sidewalls of the first cavity 401 to ensure proper alignment of the top plungers 408 with respective LGA pads 308 on the back side of the substrate 300 of the package structure 30 in a similar manner as was described previously in FIG. 14B for the alignment of the top plungers 408 with respective LGA pads 308 on the back side of the substrate 300 of the package structure 10. The fixture 400 is designed to securely hold and support the package structure 30 in place during electrical testing and prevent lateral movement of the package structure 30 during the electrical testing. After the package structure is positioned within the first cavity 401 of the fixture 400, each top plunger 408 of each socket pin 405 is in physical and electrical contact with a respective LGA pad 308 on the substrate 300 ensuring electrical connection between the package structure 30 and the PCB 418 through the socket pins 405.

In addition, when the package structure 30 is inserted into and positioned within the first cavity 401 of the fixture 400, a portion of the die 68A/B and a portion of the TEC module 426 extends into the second cavity 403. For example, the portion of the TEC module 426 and the portion of the die 68A/B may extend into the second cavity 403 such that a bottom surface of the TEC module 426 is in physical contact with a bottom surface of the second cavity 403. After the package structure 30 is inserted into and positioned within the first cavity 401 and the second cavity 403 of the fixture 400, a portion of the package structure 30 may also protrude above top surfaces of the fixture 400 and above the first cavity 401. In an embodiment, a gap is disposed between the bottom surface of the second cavity 403 and the bottom surface of the TEC module 426. In an embodiment, a first gap is disposed between a first sidewall of the top portion 402 and a sidewall of the TEC module 426. In an embodiment, a second gap is disposed between a second sidewall of the top portion 402 and a sidewall of the TEC module 426, wherein a width of the first gap is greater than a width of the second gap, and wherein the first gap is higher than the second gap.

After the package structure 30 is inserted and positioned within the first cavity 401 and the second cavity 403 of the fixture 400, the electrical testing of the package structure 30 is then performed in a similar manner as was described previously in FIG. 14B for the electrical testing of the package structure 10. During the electrical testing, a direct electric current may be applied to the semiconductor junctions (e.g., where an n-type material contacts a p-type material) of the TEC module 426, to facilitate the absorbing of heat on sidewalls and a top surface of the TEC module 426 that are adjacent to the die 68A/B, and the releasing of heat on a bottom surface of the TEC module 426. This temperature differential enables the TEC module 426 to cool the package structure 30 (including the die 68A/B) as the electrical testing is being performed.

After the electrical testing of the package structure 30 is performed, the package structure 30 may be removed from the first cavity 401 and the second cavity 403 of the fixture 400, thereby de-coupling the component 15 from the package structure 30. In an embodiment, further processes may then be performed on the package structure 30.

Advantages may be achieved as a result of inserting and positioning the package structure 30 within the first cavity 401 and the second cavity 403 of the fixture 400, such that electrical connection is established between the package structure 30 and the PCB 418 through the socket pins 405. The package structure 30 may comprise the die 68A/B that is embedded within the TEC module 426. The die 68A/B may be embedded within the TEC module 426 by attaching the die 68A/B to a bottom surface and sidewalls of the cavity within the TEC module 426 through the use of the adhesive layer 430 (e.g., a die attach film). The adhesive layer 430 may be disposed on the sidewalls and the edge portions of the bottom surface within the cavity prior to placing the die 68A/B in the cavity. In addition, the TIM 428 may be applied to the center portion of the bottom surface of the die 68A/B and/or the center portion of the bottom surface within the cavity prior to placing the die 68A/B in the cavity. The TEC module 426 and the die 68A/B embedded within the TEC module 426 are then coupled to the back side of the substrate 300. The TEC module 426 is in physical and thermal contact with the die 68A/B by way of TIM 428. A direct electric current may be applied to the semiconductor junctions (e.g., where an n-type material contacts a p-type material) of the TEC module 426. These advantages include enhanced cooling of the package structure 30 (e.g., including the die 68A/B on the back side of the substrate 300) from the back side of the substrate 300 during electrical testing of the package structure 30. This enhanced cooling may allow the bonding and utilization of a greater number of dies in the package structure 30 on both the front side and the back side of the substrate 300, since the enhanced cooling may adequately accommodate the additional heat generated by an increased number of dies. In addition, the enhanced cooling of the package structure 30 (e.g., including the die 68A/B on the backside of the substrate 300) from the back side of the substrate 300 efficiently eliminates heat traps and mitigates hot spots during electrical testing, which results in improved thermal management and overall temperature control of the package structure 30. This further allows for power to be delivered to the package structure 30 from the back side of the substrate 300 without the formation of hot spots and heat traps within the package structure 30.

In other embodiments, the PCB 418 serves functional requirements as part of a final electronic product, and the PCB 418 and the fixture 400 are permanently assembled and coupled to the package structure 30 to form a combined package structure 35. The PCB 418 may comprise electronic components, circuits, and connections necessary for the intended operation of the combined package structure 35. This includes microprocessors, memory, sensors, and other components. In addition, The PCB 418 may also integrate various other devices and packages, expanding its functionality and accommodating diverse electronic components beyond the combined package structure 35. After the package structure 30 is positioned within the first cavity 401 and the second cavity 403 of the fixture 400, a reflow process (similar to the reflow process described previously in FIG. 14B used to couple each of the socket pins 405 to a respective LGA pad 308) is used to facilitate the formation of a solder joint between each of the socket pins 405 and a respective LGA pad 308 on the substrate 300. In this way the package structure 30 is coupled to the fixture 400 and the substrate 300 to form the combined package structure 35. In an embodiment, after the package structure 30 is positioned within the first cavity 401 and the second cavity 403 of the fixture 400 and coupled to the socket pins 405, a bottom surface of the TEC module 426 of the package structure 30 is in physical contact with a bottom surface of the second cavity 403 (e.g., a top surface of the bottom portion 404 of the fixture 400).

Advantages may be achieved as a result of inserting and positioning the package structure 30 within the first cavity 401 and the second cavity 403 of the fixture 400, and coupling the package structure 30 to the fixture 400 such that electrical connection is established between the package structure 30 and the PCB 418 through the socket pins 405. The package structure 30 may comprise the die 68A/B that is embedded within the TEC module 426. The die 68A/B may be embedded within the TEC module 426 by attaching the die 68A/B to a bottom surface and sidewalls of the cavity within the TEC module 426 through the use of the adhesive layer 430 (e.g., a die attach film). The adhesive layer 430 may be disposed on the sidewalls and the edge portions of the bottom surface within the cavity prior to placing the die 68A/B in the cavity. In addition, the TIM 428 may be applied to the center portion of the bottom surface of the die 68A/B and/or the center portion of the bottom surface within the cavity prior to placing the die 68A/B in the cavity. The TEC module 426 and the die 68A/B embedded within the TEC module 426 are then coupled to the back side of the substrate 300. The TEC module 426 is in physical and thermal contact with the die 68A/B by way of the TIM 428. A direct electric current may be applied to the semiconductor junctions (e.g., where an n-type material contacts a p-type material) of the TEC module 426. These advantages include enhanced cooling of the package structure 30 (e.g., including the die 68A/B on the back side of the substrate 300) from the back side of the substrate 300 when the combined package structure 35 is in operation. This enhanced cooling may allow the bonding and utilization of a greater number of dies in the package structure 10 on both the front side and the back side of the substrate 300, since the enhanced cooling may adequately accommodate the additional heat generated by an increased number of dies. In addition, the enhanced cooling of the package structure 10 (e.g., including the die 68A/B on the backside of the substrate 300) from the back side of the substrate 300 efficiently eliminates heat traps and mitigates hot spots during operation of the combined package structure 35, which results in improved thermal management and overall temperature control of the package structure 10. This further allows for power to be delivered to the package structure 10 from the back side of the substrate 300 without the formation of hot spots and heat traps within the package structure 10.

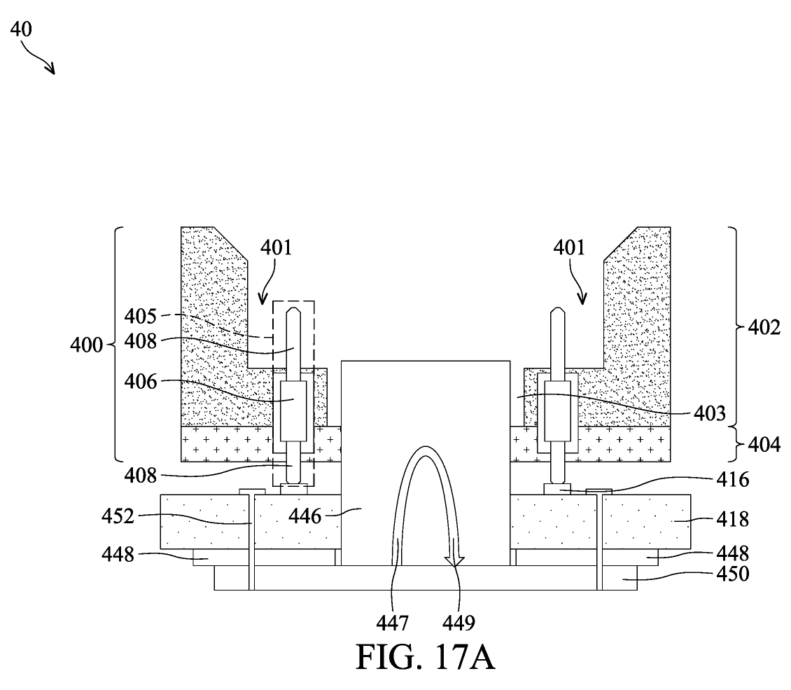

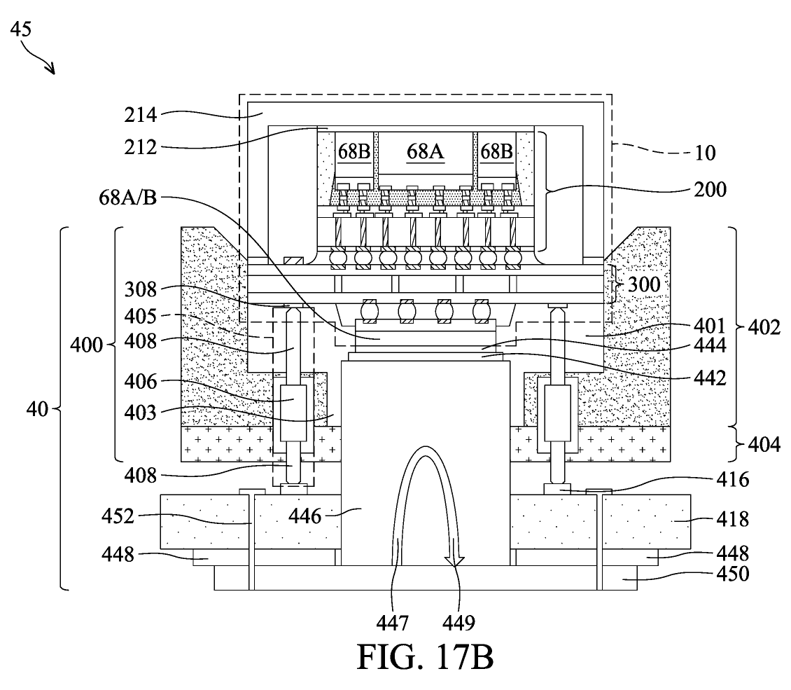

FIGS. 17A and 17B illustrate an alternative embodiment. Unless specified otherwise, like reference numerals in this embodiment (and subsequently discussed embodiments) represent like components in the embodiment shown in FIGS. 1 -16B formed by like processes. Accordingly, the process steps and applicable materials may not be repeated herein. FIG. 17A illustrates a component 40 that is used to establish temporary electrical connections between the package structure 10 shown previously in FIG. 13 and specific test points on the PCB 418. After the temporary electrical connections are established, the electrical characteristics, functionality, and performance of the package structure 10 can be assessed and tested.

The component 40 may be similar to the component 15 described previously in FIG. 14A, except that the component 40 does not comprise the TEC module 410 disposed within the second cavity 403 of the fixture 400. Instead, the component 40 comprises a cold plate 446 (e.g., a heat exchanger device designed to absorb and transfer heat away from a particular component) that may extend through a portion of the first cavity 401 of the fixture 400, the second cavity 403 of the fixture 400, and the bottom portion 404 of the fixture 400. In an embodiment, the cold plate 446 may extend through the second cavity 403 and the bottom portion 404 of the fixture 400, but does not extend through any portion of the first cavity 401. The cold plate 446 may also extend through the PCB 418 such that the cold plate 446 protrudes below a bottom surface of the PCB 418. In an embodiment, the cold plate 446 may be in physical contact with sidewalls of the bottom portion 404 of the fixture 400, and sidewalls of the PCB 418.

The cold plate 446 may comprise a thermally conductive material such as aluminum, copper, or the like. The cold plate 446 may comprise internal channels or passages through which a cooling fluid, such as water, a specialized coolant, or the like, circulates. The cold plate 446 may comprise inlet ports 447 and outlet ports 449 that facilitate the entry and exit, respectively, of the cooling fluid. The cooling fluid absorbs heat from components as it circulates through the internal channels.

The cold plate 446 may be secured in place by a combination of a backing plate 450 and fasteners 452. For example, the backing plate 450 may comprise a metal or another rigid material, and is positioned on an opposite side of the PCB 418 as the fixture 400, such that a top surface of the backing plate 450 is in physical contact with a bottom surface of the cold plate 446. The backing plate serves as structural support for the cold plate 446. In some embodiments, additional support structures such as support plates 448 may be used to provide extra stability and fill spaces between the PCB 418 and the backing plate 450. The support plates 448 may comprise similar materials to the materials of the backing plate 450. Fasteners 452 (e.g., screws) may be used to secure the cold plate 446 in place. The fasteners 452 may extend through the PCB 418, through the support plates 448, and through the backing plate 450.

In FIG. 17B, the package structure 10 is then inserted into and positioned within the first cavity 401 of the fixture 400 of the component 40. When the package structure 10 is inserted into and positioned within the first cavity 401 of the fixture 400, a portion of the package structure 10 is secured between sidewalls of the first cavity 401 to ensure proper alignment of the top plungers 408 with respective LGA pads 308 on the back side of the substrate 300 of the package structure 10 in a similar manner as was described previously in FIG. 14B for the alignment of the top plungers 408 with respective LGA pads 308 on the back side of the substrate 300 of the package structure 10. The fixture 400 is designed to securely hold and support the package structure 10 in place during electrical testing and prevent lateral movement of the package structure 10 during the electrical testing. After the package structure 10 is inserted into and positioned within the first cavity 401 of the fixture 400, a portion of the package structure 10 may also protrude above top surfaces of the fixture 400 and above the first cavity 401. After the package structure 10 is positioned within the first cavity 401 of the fixture 400, each top plunger 408 of each socket pin 405 is in physical and electrical contact with a respective LGA pad 308 on the substrate 300 ensuring electrical connection between the package structure 10 and the PCB 418 through the socket pins 405. In addition, after the package structure 10 is positioned within the first cavity 401 of the fixture 400, the cold plate 446 may be in physical contact with a bottom surface of the die 68A/B that is coupled to the back side of the substrate 300 by way of a TIM 442 disposed between the cold plate 446 and the die 68A/B. The TIM 442 may comprise similar materials and may be applied in a similar manner as was described previously in FIG. 13 for the TIM 212 and the TIM 218. For example, a metal layer 444 may be disposed on a bottom surface of the die 68A/B, the die 68A/B being coupled to the back side of the substrate 300. In an embodiment, the metal layer 444 may comprise titanium, copper, nickel vanadium, gold, a combination thereof, or the like. The TIM 442 may be applied to a top surface of the cold plate 446 and/or a bottom surface of the metal layer 444. After the package structure 10 is positioned within the first cavity 401 of the fixture 400, the die 68A/68B is coupled to the cold plate 446 by way of the TIM 442. The circulating cooling fluid in the cold plate 446 absorbs heat from the package structure 10 (e.g., including the die 68A/B that is coupled to the back side of the substrate 300) and carries it away from the cold plate 446, thereby facilitating the cooling of the package structure 10.

After the package structure 10 is inserted and positioned within the first cavity 401 of the fixture 400, the electrical testing of the package structure 10 can then be performed as described previously in FIG. 14B. During the electrical testing, the circulating cooling fluid in the cold plate 446 absorbs heat from the package structure 10 (e.g., including the die 68A/B that is coupled to the back side of the substrate 300) and carries it away from the cold plate 446, thereby facilitating the cooling of the package structure 10. After the electrical testing of the package structure 10 is performed, the package structure 10 may be removed from the first cavity 401 of the fixture 400, thereby de-coupling the component 40 from the package structure 10. In an embodiment, further processes may then be performed on the package structure 10.

Advantages may be achieved as a result of inserting and positioning the package structure 10 within the first cavity 401 of the fixture 400, such that electrical connection is established between the package structure 10 and the PCB 418 through the socket pins 405. The cold plate 446 may extend through a portion of the first cavity 401 of the fixture 400, the second cavity 403 of the fixture 400, and the bottom portion 404 of the fixture 400. In an embodiment, the cold plate 446 may extend through the second cavity 403 and the bottom portion 404 of the fixture 400, but does not extend through any portion of the first cavity 401. The cold plate 446 may also extend through the PCB 418 such that the cold plate 446 protrudes below a bottom surface of the PCB 418. In an embodiment, the cold plate 446 may be in physical contact with sidewalls of the bottom portion 404 of the fixture 400, and sidewalls of the PCB 418. The cold plate 446 may be in physical and thermal contact with a bottom surface of the die 68A/B, the die 68A/B being coupled to the back side of the substrate 300 by way of the TIM 442 that is disposed between the cold plate 446 and the die 68A/B. These advantages include enhanced cooling of the package structure 10 (e.g., including the die 68A/B on the back side of the substrate 300) from the back side of the substrate 300 during electrical testing of the package structure 10. This enhanced cooling may allow the bonding and utilization of a greater number of dies in the package structure 10 on both the front side and the back side of the substrate 300, since the enhanced cooling may adequately accommodate the additional heat generated by an increased number of dies. In addition, the enhanced cooling of the package structure 10 (e.g., including the die 68A/B on the backside of the substrate 300) from the back side of the substrate 300 efficiently eliminates heat traps and mitigates hot spots during electrical testing, which results in improved thermal management and overall temperature control of the package structure 10. This further allows for power to be delivered to the package structure 10 from the back side of the substrate 300 without the formation of hot spots and heat traps within the package structure 10.

In other embodiments, the PCB 418 serves functional requirements as part of a final electronic product, and the PCB 418 and the fixture 400 are permanently assembled and coupled to the package structure 10 to form a combined package structure 45. The PCB 418 may comprise electronic components, circuits, and connections necessary for the intended operation of the combined package structure 45. This includes microprocessors, memory, sensors, and other components. In addition, The PCB 418 may also integrate various other devices and packages, expanding its functionality and accommodating diverse electronic components beyond the combined package structure 45. After the package structure 10 is positioned within the first cavity 401 of the fixture 400, a reflow process (similar to the reflow process described previously in FIG. 14B used to couple each of the socket pins 405 to a respective LGA pad 308) is used to facilitate the formation of a solder joint between each of the socket pins 405 and a respective LGA pad 308 on the substrate 300. In this way the package structure 10 is coupled to the fixture 400 and the substrate 300 to form the combined package structure 45. In an embodiment, after the package structure 10 is positioned within the first cavity 401 of the fixture 400 and coupled to the socket pins 405, the cold plate 446 may be in physical contact with a bottom surface of the die 68A/B that is coupled to the back side of the substrate 300 by way of a TIM 442.

Advantages may be achieved as a result of inserting and positioning the package structure 10 within the first cavity 401 of the fixture 400, and coupling the package structure 10 to the fixture 400 such that electrical connection is established between the package structure 10 and the PCB 418 through the socket pins 405. The cold plate 446 may extend through a portion of the first cavity 401 of the fixture 400, the second cavity 403 of the fixture 400, and the bottom portion 404 of the fixture 400. In an embodiment, the cold plate 446 may extend through the second cavity 403 and the bottom portion 404 of the fixture 400, but does not extend through any portion of the first cavity 401. The cold plate 446 may also extend through the PCB 418 such that the cold plate 446 protrudes below a bottom surface of the PCB 418. In an embodiment, the cold plate 446 may be in physical contact with sidewalls of the bottom portion 404 of the fixture 400, and sidewalls of the PCB 418. A top surface of the cold plate 446 may be in physical and thermal contact with a bottom surface of the die 68A/B that is coupled to the back side of the substrate 300 by way of the TIM 442 disposed between the cold plate 446 and the die 68A/B. These advantages include enhanced cooling of the package structure 10 (e.g., including the die 68A/B on the back side of the substrate 300) from the back side of the substrate 300 when the combined package structure 45 is in operation. This enhanced cooling may allow the bonding and utilization of a greater number of dies in the package structure 10 on both the front side and the back side of the substrate 300, since the enhanced cooling may adequately accommodate the additional heat generated by an increased number of dies. In addition, the enhanced cooling of the package structure 10 (e.g., including the die 68A/B on the backside of the substrate 300) from the back side of the substrate 300 efficiently eliminates heat traps and mitigates hot spots during operation of the combined package structure 45, which results in improved thermal management and overall temperature control of the package structure 10. This further allows for power to be delivered to the package structure 10 from the back side of the substrate 300 without the formation of hot spots and heat traps within the package structure 10.

In accordance with an embodiment, a method includes forming a package structure, where forming the package structure includes attaching a package component to a front side of a package substrate, where the package component includes a first die; and attaching a second die to a back side of the package substrate; and inserting a portion of the package structure into a first cavity of a fixture, where the fixture includes a thermoelectric cooling (TEC) module that is disposed in a second cavity of the fixture, where the second cavity of the fixture is disposed within a bottom surface of the first cavity, where after inserting the portion of the package structure into the first cavity of the fixture, the second die is in thermal contact with the TEC module, and where the fixture is coupled to a printed circuit board (PCB). In an embodiment, the package structure includes a heat spreader attached to the package substrate, and where the heat spreader surrounds the package component. In an embodiment, after inserting the portion of the package structure into the first cavity of the fixture, the package structure is electrically coupled to the PCB using socket pins of the fixture. In an embodiment, the method further includes testing the package structure by applying electrical signals to the package structure through the PCB. In an embodiment, testing the package structure further includes applying a direct electric current to semiconductor junctions of the TEC module. In an embodiment, the method further includes after testing the package structure, de-coupling the package structure from the fixture. In an embodiment, a width of the first cavity is greater than a width of the second cavity, and where the first cavity is higher than the second cavity. In an embodiment, a first metal layer is disposed over the TEC module, and a second metal layer is disposed on a bottom surface of the second die. In an embodiment, the method further includes before inserting the portion of the package structure into the first cavity of the fixture, applying a thermal interface material (TIM) to a top surface of the first metal layer or a bottom surface of the second metal layer.

In accordance with an embodiment, a method includes forming a package structure, where forming the package structure includes bonding a first die and an interposer to a first side of a package substrate, the interposer being disposed between the first die and the package substrate; and bonding a thermoelectric cooling (TEC) module and a second die to a back side of the package substrate, where the second die is embedded in the TEC module; and inserting a first portion of the package structure into a first cavity of a fixture, and a second portion of the package structure into a second cavity of the fixture, where the second cavity of the fixture is disposed within a bottom surface of the first cavity, where the second portion of the package structure includes portions of the TEC module and the second die, where the fixture is coupled to a printed circuit board (PCB). In an embodiment, sidewalls of the second die are attached to sidewalls of the TEC module using an adhesive layer. In an embodiment, a thermal interface material (TIM) is disposed between a bottom surface of the second die and the TEC module. In an embodiment, the TIM includes indium. In an embodiment, after inserting the first portion of the package structure into the first cavity of the fixture, and the second portion of the package structure into the second cavity of the fixture, the package structure is electrically coupled to the PCB using socket pins of the fixture. In an embodiment, the method further includes testing the package structure by applying electrical signals to the package structure through the PCB.

In accordance with an embodiment, a device includes a package structure including a package component bonded to a first side of a package substrate, the package component including a first die; and a second die bonded to a second side of the package substrate; and a fixture including a first cavity and a thermoelectric cooling (TEC) module disposed below the first cavity, where a portion of the package structure is disposed in the first cavity, where the portion of the package structure includes the second die, and where the second die is in thermal contact with the TEC module. In an embodiment, the device further includes a printed circuit board (PCB) that is coupled to the fixture. In an embodiment, the device further includes a printed circuit board (PCB) that is coupled to the fixture. In an embodiment, the package structure is electrically coupled to the PCB using socket pins of the fixture. In an embodiment, the device further includes a first metal layer disposed over the TEC module, and a second metal layer disposed on a bottom surface of the second die. In an embodiment, a thermal interface material (TIM) that is disposed between the first metal layer and the second metal layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a package structure comprising:
a package component bonded to a first side of a package substrate, the package component comprising a first die; and
a second die bonded to a second side of the package substrate; and
a fixture comprising a first cavity and a thermoelectric cooling (TEC) module disposed below the first cavity, wherein a portion of the package structure is disposed in the first cavity, wherein the portion of the package structure comprises the second die, and wherein the second die is in thermal contact with the TEC module.

2. The device of claim 1, further comprising a printed circuit board (PCB) that is coupled to the fixture.

3. The device of claim 2, wherein the package structure is electrically coupled to the PCB using socket pins of the fixture.

4. The device of claim 2, further comprising a first metal layer disposed over the TEC module, and a second metal layer disposed on a bottom surface of the second die.

5. The device of claim 4, further comprising a thermal interface material (TIM) that is disposed between the first metal layer and the second metal layer.

6. A device comprising:
a package structure comprising:
a first die and an interposer bonded to a first side of a package substrate; and
a second die bonded to a second side of the package substrate; and
a fixture comprising a thermoelectric cooling (TEC) module, the fixture comprising a cavity, wherein a portion of the TEC module is disposed below a bottom surface of the cavity, wherein a portion of the package structure is disposed in the cavity, wherein the portion of the package structure comprises the second die, and wherein the second die is disposed over and in physical contact with the TEC module.

7. The device of claim 6, further comprising a first metal layer disposed over the TEC module, and a second metal layer disposed on a bottom surface of the second die.

8. The device of claim 7, further comprising a thermal interface material (TIM) disposed between the first metal layer and the second metal layer.

9. The device of claim 8, wherein the TIM comprises indium.

10. The device of claim 6, wherein a width of the package substrate is greater than a width of the TEC module.

11. The device of claim 6, further comprising a heat spreader attached to the package substrate, and wherein the heat spreader surrounds the first die and the interposer.

12. The device of claim 6, further comprising a printed circuit board (PCB) coupled to the fixture, wherein the package structure is electrically coupled to the PCB through socket pins of the fixture.

13. The device of claim 6, wherein the TEC module is attached to a first portion of the fixture by an adhesive layer.

14. A device comprising:
a package structure comprising:
a package substrate;
a first die and an interposer bonded to a first side of the package substrate;
a heat spreader attached to the first side of the package substrate by an adhesive material, the heat spreader surrounding and disposed over the first die and the interposer; and
a second die bonded to a second side of the package substrate, wherein the package substrate is disposed between the second die and the first die; and
a fixture comprising a cavity and a thermoelectric cooling (TEC) module, wherein the second die of the package structure is disposed in the cavity and thermally coupled to the TEC module.

15. The device of claim 14, wherein the heat spreader comprises a thermal lid or a thermal ring.

16. The device of claim 14, wherein the heat spreader comprises copper, steel, or iron.

17. The device of claim 14, wherein the heat spreader is also attached to a top surface of the first die using a thermal interface material (TIM).

18. The device of claim 17, wherein the TIM comprises indium.

19. The device of claim 17, further comprising a cooling device coupled to a top surface of the heat spreader.

20. The device of claim 14, further comprising a printed circuit board (PCB) coupled to the fixture, wherein the package structure is electrically coupled to the PCB through socket pins of the fixture.
